(19) United States
(12) Patent Application Publication
(10) Pub. No.: US 2011/0042733 A1
(43) Pub. Date: Feb. 24, 2011

(54) SEMICONDUCTOR DEVICE AND METHOD OF FORMING THE SAME

(75) Inventors: Kazushi Komeda, Tokyo (JP); Takashi Miyajima, Tokyo (JP); Shigeru Sugioka, Tokyo (JP); Takashi Miyamura, Tokyo (JP)

Correspondence Address: YOUNG & THOMPSON, 209 Madison Street, Suite 500, Alexandria, VA, 22314, US

(73) Assignee: ELPIDA MEMORY, INC., Tokyo (JP)

(21) Appl. No.: 12/857,643

(22) Filed: Aug. 17, 2010

(30) Foreign Application Priority Data
Aug. 19, 2009 (JP) 2009-190294

(51) Int. Cl. H01L 27/108; H01L 23/00

(52) U.S. Cl. 257/296; 257/618; 257/E23.194; 257/E27.097

(57) ABSTRACT

A semiconductor device includes a plurality of first electrodes standing over a substrate, and a supporter that supports the plurality of first electrodes in standing. The supporter includes a stack of first and second supporting films. The first supporting film has a compressive stress. The second supporting film has a tensile stress.

### BACKGROUND OF THE INVENTION

1. Field of the Invention

The invention relates to a semiconductor device and a method of forming the same. More particularly, the invention relates to a semiconductor device having a supporter capable of preventing the occurrence of cracks in a supporter that supports a bottom electrode of a capacitor element and a method of forming the same. Priority is claimed on Japanese Patent Application No. 2009-190294, filed Aug. 19, 2009, the content of which is incorporated herein by reference.

2. Description of the Related Art

As shrinkage of semiconductor devices have been increasing, the area allocated for memory cells of a dynamic random access memory (hereinafter referred to as DRAM) device has been reducing.

Memory cells of a DRAM device ensure a sufficient electrostatic capacitance by using capacitors including bottom electrodes standing vertically such as a crown, cylindrical, pillar, or columnar shape. Such bottom electrodes utilize outer wall surfaces with a large surface area.

Bottom electrodes with a 3-dimensional shape such as a pillar shape will have a small bottom surface area as compared to their toll height. These bottom electrodes are thus unstable. When an interlayer insulating film such as a silicon oxide film (SiO₂) is selectively removed using a chemical solution mainly containing hydrofluoric acid (HF) during the manufacturing process of capacitors (hereinafter referred to as wet-etching process) so as to expose the outer walls of the bottom electrodes, the bottom electrodes can collapse and a short-circuit to an adjacent bottom electrode can be formed.

Japanese Unexamined Patent Application, First Publications, Nos. JP-A-2003-297952, JP-A-2003-142605, JP-A-2008-283026, JP-A-2008-193088, and JP-A-2007-234743 disclose techniques for disposing a supporter between bottom electrodes in order to prevent collapses of the bottom electrodes.

Japanese Unexamined Patent Application, First Publication, No. JP-A-2003-297952 relates to a semiconductor device having cylindrical capacitors and a method of forming the same and discloses a support base film that prevents collapse of the bottom electrodes of cylindrical capacitors. Moreover, it is stated that the support base film is formed from a silicon nitride (SiN) film.

Japanese Unexamined Patent Application, First Publication, No. JP-A-2003-142605 relates to a semiconductor storage device and a method of forming the same and discloses an insulator mount that connects capacitors. Moreover, it is stated that the insulator mount is formed from a silicon nitride (SiN) film.

Japanese Unexamined Patent Application, First Publication, No. JP-A-2008-283026 relates to a semiconductor device manufacturing method and a semiconductor device and discloses a plate-like support that is formed from a nitride film so as to connect and support the bottom electrodes of plural capacitors. Japanese Unexamined Patent Application, First Publication, No.

JP-A-2008-193088 relates to a semiconductor device and a forming method thereof and discloses at least one support pattern that extends vertically between the lower capacitor electrodes. Moreover, it is stated that the support pattern contains tantalum oxide.

Japanese Unexamined Patent Application, First Publication, No. JP-A-2007-234743 relates to a semiconductor storage device and a semiconductor storage device manufacturing method and discloses an interlayer insulating layer which is formed from a silicon nitride film by a high density plasma chemical vapor deposition method and is formed on a ferroelectric capacitor.

### SUMMARY

In one embodiment, a semiconductor device may include, but is not limited to, a plurality of first electrodes standing over a substrate, and a supporter that supports the plurality of first electrodes in standing. The supporter may include, but is not limited to, a stack of first and second supporting films. The first supporting film has a compressive stress. The second supporting film has a tensile stress.

In another embodiment, a semiconductor device may include, but is not limited to, a plurality of memory cells and a supporter. Each memory cell may include, but is not limited to, a transistor and a capacitor. The capacitor may include, but is not limited to, first and second electrodes and an insulating film between the first and second electrodes. The first electrode is connected to the transistor electrically. The supporter connects the first electrodes of the plurality of memory cells to each other. The supporter may include, but is not limited to, a stack of first and second supporting films. The first supporting film has a compressive stress. The second supporting film has a tensile stress.

In still another embodiment, a semiconductor device may include, but is not limited to, a plurality of first electrodes standing over a substrate; and a supporter that connects the plurality of first electrodes to each other. The supporter has a stress-relaxing multi-layer structure which may include, but is not limited to, first and second supporting layers which are different in stress direction from each other.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a plan view of illustrating a semiconductor device including a plurality of memory cell regions in accordance with a first preferred embodiment of the present invention;

FIG. 2 is a schematic plan view of illustrating the memory cell region included in the semiconductor device of FIG. 1;

FIG. 3 is an enlarged plan view of illustrating a part of the memory cell region of FIG. 2;

FIG. 4 is another enlarged plan view of illustrating another part of the memory cell region of FIG. 2;

FIG. 5A is a fragmentary cross sectional elevation view illustrating the semiconductor device, taken along an A-A′ line of FIG. 2;

FIG. 5B is a fragmentary cross sectional elevation view illustrating the semiconductor device, taken along a B-B′ line of FIG. 2;

FIG. 6A is a fragmentary cross sectional elevation view illustrating a semiconductor device in a step involved in a method of forming the semiconductor device, taken along an A-A′ line of FIG. 2;

FIG. 6B is a fragmentary cross sectional elevation view illustrating the semiconductor device in the step of FIG. 6A, involved in the method of forming the semiconductor device, taken along a B-B′ line of FIG. 2;

FIG. 7A is a fragmentary cross sectional elevation view illustrating a semiconductor device in a step, subsequent to the step of FIGS. 6A and 6B, involved in the method of forming the semiconductor device, taken along the A-A′ line of FIG. 2;

FIG. 7B is a fragmentary cross sectional elevation view illustrating the semiconductor device in the step of FIG. 7A, subsequent to the step of FIGS. 6A and 6B, involved in the method of forming the semiconductor device, taken along the B-B′ line of FIG. 2;

FIG. 8A is a fragmentary cross sectional elevation view illustrating a semiconductor device in a step, subsequent to the step of FIGS. 7A and 7B, involved in the method of forming the semiconductor device, taken along the A-A′ line of FIG. 2;

FIG. 8B is a fragmentary cross sectional elevation view illustrating the semiconductor device in the step of FIG. 8A, subsequent to the step of FIGS. 7A and 7B, involved in the method of forming the semiconductor device, taken along the B-B′ line of FIG. 2;

FIG. 9A is a fragmentary cross sectional elevation view illustrating a semiconductor device in a step, subsequent to the step of FIGS. 8A and 8B, involved in the method of forming the semiconductor device, taken along the A-A′ line of FIG. 2;

FIG. 9B is a fragmentary cross sectional elevation view illustrating the semiconductor device in the step of FIG. 9A, subsequent to the step of FIGS. 8A and 8B, involved in the method of forming the semiconductor device, taken along the B-B′ line of FIG. 2;

FIG. 10A is a fragmentary cross sectional elevation view illustrating a semiconductor device in a step, subsequent to the step of FIGS. 9A and 9B, involved in the method of forming the semiconductor device, taken along the A-A′ line of FIG. 2;

FIG. 10B is a fragmentary cross sectional elevation view illustrating the semiconductor device in the step of FIG. 10A, subsequent to the step of FIGS. 9A and 9B, involved in the method of forming the semiconductor device, taken along the B-B′ line of FIG. 2;

FIG. 11A is a fragmentary cross sectional elevation view illustrating a semiconductor device in a step, subsequent to the step of FIGS. 10A and 10B, involved in the method of forming the semiconductor device, taken along the A-A′ line of FIG. 2; FIG. 11B is a fragmentary cross sectional elevation view illustrating the semiconductor device in the step of FIG. 11A, subsequent to the step of FIGS. 10A and 10B, involved in the method of forming the semiconductor device, taken along the B-B′ line of FIG. 2;

FIG. 12A is a fragmentary cross sectional elevation view illustrating a semiconductor device in a step, subsequent to the step of FIGS. 11A and 11B, involved in the method of forming the semiconductor device, taken along the A-A′ line of FIG. 2;

FIG. 12B is a fragmentary cross sectional elevation view illustrating the semiconductor device in the step of FIG. 12A, subsequent to the step of FIGS. 11A and 11B, involved in the method of forming the semiconductor device, taken along the B-B′ line of FIG. 2;

FIG. 13A is a fragmentary cross sectional elevation view illustrating a semiconductor device in a step, subsequent to the step of FIGS. 12A and 12B, involved in the method of forming the semiconductor device, taken along the A-A′ line of FIG. 2;

FIG. 13B is a fragmentary cross sectional elevation view illustrating the semiconductor device in the step of FIG. 13A, subsequent to the step of FIGS. 12A and 13B, involved in the method of forming the semiconductor device, taken along the B-B′ line of FIG. 2;

FIG. 14A is a fragmentary cross sectional elevation view illustrating a semiconductor device in a step, subsequent to the step of FIGS. 13A and 13B, involved in the method of forming the semiconductor device, taken along the A-A′ line of FIG. 2;

FIG. 14B is a fragmentary cross sectional elevation view illustrating the semiconductor device in the step of FIG. 14A, subsequent to the step of FIGS. 13A and 13B, involved in the method of forming the semiconductor device, taken along the B-B′ line of FIG. 2;

FIG. 15 is a plan view of illustrating a semiconductor device including a plurality of memory cell regions in accordance with a second preferred embodiment of the present invention;

FIG. 16 is a schematic plan view of illustrating the memory cell region included in the semiconductor device of FIG. 15;

FIG. 17A is a fragmentary cross sectional elevation view illustrating the semiconductor device, taken along a C-C′ line of FIG. 16;

FIG. 17B is a fragmentary cross sectional elevation view illustrating the semiconductor device, taken along a D-D′ line of FIG. 16;

FIG. 18A is a fragmentary cross sectional elevation view illustrating a semiconductor device in a step involved in a method of forming the semiconductor device, taken along an A-A′ line of FIG. 16;

FIG. 18B is a fragmentary cross sectional elevation view illustrating the semiconductor device in the step of FIG. 18A, involved in the method of forming the semiconductor device, taken along a B-B′ line of FIG. 16;

FIG. 19 is a plan view of illustrating a semiconductor device including a plurality of memory cell regions in accordance with a third preferred embodiment of the present invention;

FIG. 20 is a schematic plan view of illustrating the memory cell region included in the semiconductor device of FIG. 19;

FIG. 21A is a fragmentary cross sectional elevation view illustrating the semiconductor device, taken along an E-E′ line of FIG. 20;

FIG. 21B is a fragmentary cross sectional elevation view illustrating the semiconductor device, taken along an F-F′ line of FIG. 20;

FIG. 22A is a fragmentary cross sectional elevation view illustrating a semiconductor device in a step involved in a method of forming the semiconductor device, taken along an E-E′ line of FIG. 20; and

FIG. 22B is a fragmentary cross sectional elevation view illustrating the semiconductor device in the step of FIG. 22A, involved in the method of forming the semiconductor device, taken along an F-F′ line of FIG. 20.

### DETAILED DESCRIPTION OF THE PREFERRED EMBODIMENTS

Before describing the present invention, the related art will be explained in detail, in order to facilitate the understanding of the present invention. As a supporter that supports the outer wall surfaces of such a bottom electrode, a silicon nitride film (Si₃N₄) having chemical resistance to hydrofluoric acid is often used since it is desirable that the supporter is not damaged by the hydrofluoric acid at the time of the wet-etching process.

The silicon nitride film is generally formed by a low pressure chemical vapor deposition (hereinafter referred to as LP-CVD) method. The LP-CVD method is one kind of thermal CVD method, which is a method that deposits a film by causing a thermal reaction in the raw material gas in a pressure atmosphere at atmospheric pressure or lower.

A silicon nitride film formed by the LP-CVD method has a strong tensile stress. Therefore, cracks resulting from the tensile stress are often formed in the supporter formed from a thin film of the silicon nitride film.

When cracks are formed in the supporter, the strength of the supporter decreases, and when the outer wall surfaces of the bottom electrodes were exposed during the wet-etching process of the manufacturing process of capacitors, the supporter was destroyed and the bottom electrodes collapsed.

Particularly, when the size of the memory cells of a DRAM device was decreased further in accordance with the demand for the miniaturization of semiconductor devices, and the size of the bottom of the bottom electrode of a capacitor was reduced further, the proportion of bottom electrodes which collapsed increased, and the likelihood of short-circuiting to an adjacent bottom electrode also increased. Thus, the yield of the DRAM device decreased.

Therefore, there is a problem in that when the outer wall surfaces of the bottom electrodes of capacitors are exposed during the wet-etching process of the manufacturing process of capacitors, cracks form in the supporter that supports the bottom electrodes. Thus, the strength of the supporter decreased, and the bottom electrodes collapsed.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a semiconductor device may include, but is not limited to, a plurality of first electrodes standing over a substrate, and a supporter that supports the plurality of first electrodes in standing. The supporter may include, but is not limited to, a stack of first and second supporting films. The first supporting film has a compressive stress. The second supporting film has a tensile stress.

In some cases, the stack of first and second supporting films may be an alternate stack of the first and second supporting films, where the number of at least one of the first and second supporting films is two or more.

In some cases, the supporter is in contact with at least upper portions of the first electrodes.

In some cases, each of the plurality of first electrodes has a cylindrical shape and an inner space.

In some cases, the supporter includes filling portions that fill at least partially the inner spaces of the plurality of first electrodes.

In some cases, the filling portions of the supporter comprise at least one of the first and second supporting films.

In some cases, each of the plurality of first electrodes has a pillar shape.

In some cases, at least one of the first and second supporting films comprises a silicon nitride film.

In some cases, the semiconductor device may include, but is not limited to, a capacitive insulating film on a side surface of the first electrode; and a second electrode on the capacitive insulating film, the first and second electrodes sandwiching the capacitive insulating film.

In some cases, the supporter may include, but is not limited to, a frame portion, and a supporting portion connected to the frame portion. The supporting portion is in contact with the plurality of first electrodes.

In another embodiment, a semiconductor device may include, but is not limited to, a plurality of memory cells and a supporter. Each memory cell may include, but is not limited to, a transistor and a capacitor. The capacitor may include, but is not limited to, first and second electrodes and an insulating film between the first and second electrodes. The first electrode is connected to the transistor electrically. The supporter connects the first electrodes of the plurality of memory cells to each other. The supporter may include, but is not limited to, a stack of first and second supporting films. The first supporting film has a compressive stress. The second supporting film has a tensile stress.

In some cases, the supporter may include, but is not limited to, a frame portion that surrounds the plurality of memory cells in plan view, and a plurality of supporting portions connected to the frame portion. The plurality of supporting portions connects the first electrodes of the plurality of memory cells to each other.

In some cases, the plurality of supporting portions are in contact with at least upper portions of the first electrodes.

In some cases, the supporter comprises an alternate stack of the first and second supporting films, where the number of at least one of the first and second supporting films is two or more.

In some cases, the first electrodes have inner spaces. The supporter includes filling portions that fill at least partially the inner spaces of the first electrodes.

In some cases, the filling portions of the supporter may include, but are not limited to, at least one of the first and second supporting films.

In some cases, at least one of the first and second supporting films may include, but is not limited to, a silicon nitride film.

In still another embodiment, a semiconductor device may include, but is not limited to, a plurality of first electrodes standing over a substrate; and a supporter that connects the plurality of first electrodes to each other. The supporter has a stress-relaxing multi-layer structure which may include, but is not limited to, first and second supporting layers which are different in stress direction from each other.

In some cases, the first supporting film has a compressive stress. The second supporting film has a tensile stress.

In some cases, the first supporting film may include, but is not limited to, a HDP-CVD silicon nitride film. The second supporting film may include, but is not limited to, at least one of an ALD silicon nitride film and a LP-CVD silicon nitride film.

In yet another embodiment, a method of forming a semiconductor device may include, but is not limited to, the following processes. A plurality of connection electrodes is formed over a semiconductor substrate. A first insulating film is formed, which covers the plurality of connection electrodes. A stack of first and second supporting films is formed over the first insulating film. The first supporting film has a compressive stress. The second supporting film has a tensile stress. A plurality of holes is formed, which penetrates the stack of first and second supporting films and the first insulating film. The holes reach the connection electrodes. A plurality of first electrodes is formed which contact with the plurality of the connection electrodes. The stack of first and second supporting films is patterned to form a supporter which contacts at least parts of the plurality of first electrodes. A wet etching process is carried out to selectively remove the first insulating film to expose outside walls of the first electrodes.

In an additional embodiment, a method of forming a semiconductor device may include, but is not limited to, the following processes. A plurality of connection electrodes is formed over a semiconductor substrate. A first insulating film is formed, which covers the plurality of connection electrodes. A plurality of holes is formed, which penetrates the first insulating film. The holes reach the connection electrodes. A plurality of first electrodes of a cylindrical shape is formed which cover the inside walls of the holes. The plurality of first electrodes contacts with the connection electrodes. A stack of first and second supporting films is formed over the first insulating film. The stack of first and second supporting films fills the inside spaces of the plurality of first electrodes of the cylindrical shape. The first supporting film has a compressive stress. The second supporting film has a tensile stress. The stack of first and second supporting films is patterned to form a supporter which contacts at least parts of the plurality of first electrodes. A wet etching process is carried out to selectively remove the first insulating film to expose outside walls of the first electrodes.

In a furthermore embodiment, a method of forming a semiconductor device may include, but is not limited to, the following processes. A plurality of connection electrodes is formed over a semiconductor substrate. A first insulating film is formed, which covers the plurality of connection electrodes. A first supporting film is formed over the first insulating film. The first supporting film has one of a compressive stress and a tensile stress. A plurality of holes is formed, which penetrates the first supporting film and the first insulating film. The holes reach the connection electrodes. A plurality of first electrodes of a cylindrical shape is formed which covers the inside walls of the holes. The plurality of first electrodes contacts with the connection electrodes. A second supporting film is formed on the first supporting film to form a stack of the first and second supporting films. The second supporting film has the other one of the compressive stress and the tensile stress. The second supporting film fills the inside spaces of the first electrodes. The stack of first and second supporting films is patterned to form a supporter which contacts at least parts of the plurality of first electrodes. A wet etching process is carried out to selectively remove the first insulating film to expose outside walls of the first electrodes.

In some cases, the first and second supporting films are silicon nitride films. The first supporting film may include, but is not limited to, an HDP-CVD silicon nitride film. The second supporting film may include, but is not limited to, at least one of an ALD silicon nitride film and an LP-CVD silicon nitride film.

In some cases, a plurality of MOS transistors which are connected through the connection electrodes to the first electrodes.

Hereinafter, embodiments of the invention will be described. The diagrams used in the description below are for describing the structure of a semiconductor device, and the size and dimensions of each part shown are different from the dimensions of an actual semiconductor device.

### First Embodiment

### Semiconductor Device

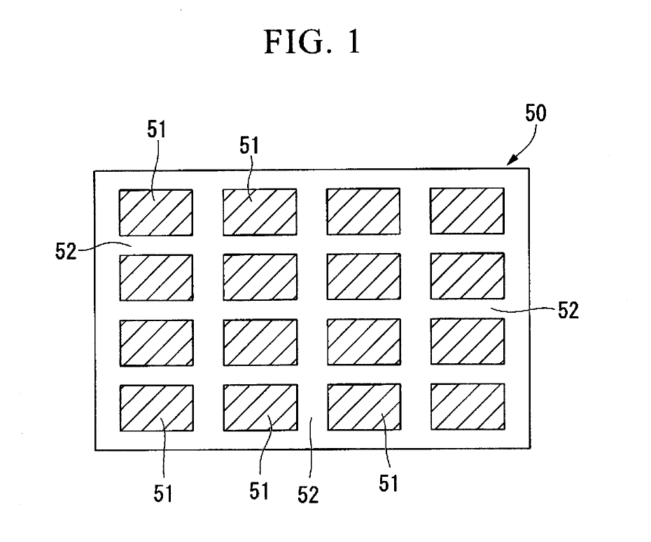

First, a semiconductor device which is a first embodiment of the invention will be described with reference to FIGS. 1 to 5.

FIG. 1 is a conceptual diagram showing an example of a top-view structure of a semiconductor device according to an embodiment of the invention.

As shown in FIG. 1, a semiconductor device 50 according to an embodiment of the present invention is a DRAM device having an approximately rectangular shape in top view. The semiconductor device 50 includes plural memory cell units 51 having an approximately rectangular shape in top view and a peripheral circuit portion 52.

The memory cell units 51 are arranged in a 4-by-4 grid form, and the peripheral circuit portion 52 is disposed in a region around the respective memory cell units 51.

The peripheral circuit portion 52 may be a sense amplifier circuit, a word-line driving circuit, and an external input/output circuit, for example. A capacitor element Ca for storage operations is not disposed in the peripheral circuit portion 52.

The layout of the memory cell units 51 shown in FIG. 1 is an example, and the shape, number, and position of the memory cell units 51 are not limited to this.

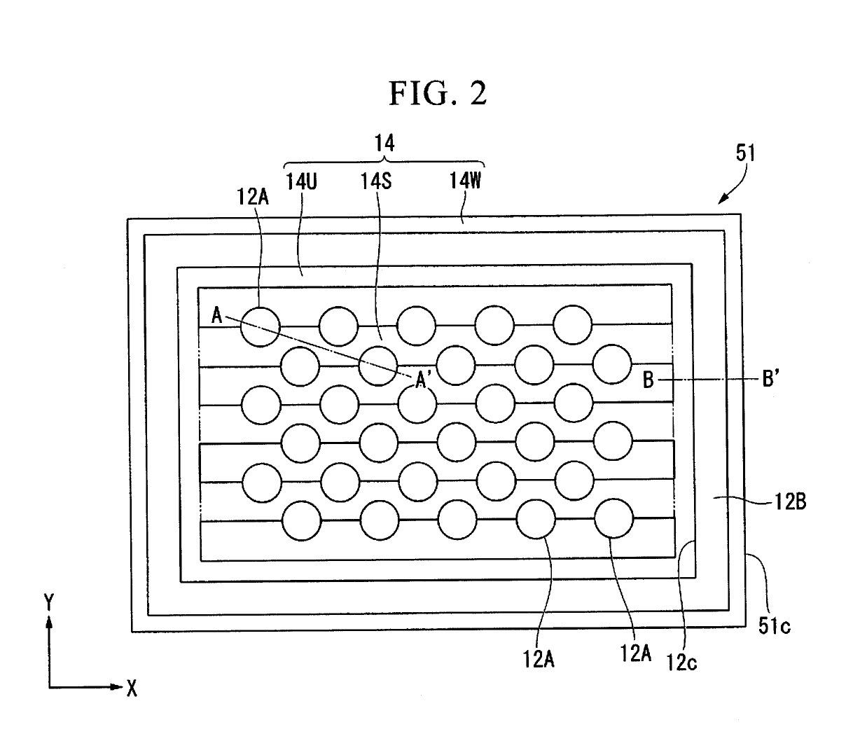

FIG. 2 is a conceptual diagram showing an example of a top-view structure of the memory cell unit 51 disposed in the semiconductor device 50. FIG. 2 shows only some of the constituent elements of the memory cell unit 51.

The direction parallel to the long side of the memory cell unit 51 will be defined as an X direction, and the direction perpendicular to the X direction will be defined as a Y direction (the same applies to the following description).

As shown in FIG. 2, an outer trench 12B is formed along an outer circumference 51c of the memory cell unit 51. The outer trench 12B is formed in a constant width at a constant distance from the outer circumference 51c.

A region surrounded by the outer trench 12B is a region in which a memory cell is formed, and formation positions 12A of the bottom electrodes of capacitors are depicted by thirty circles. The formation positions 12A of the bottom electrodes of capacitors are openings which are provided on an interlayer insulating film in order to form the bottom electrodes. Thus, the formation positions 12A will be referred to as openings 12A.

The layout of the openings 12A shown in FIG. 2 is an example, and the shape, number, and position of the openings 12A are not limited to this.

As shown in FIG. 2, a multi-stack film 14 is formed on the memory cell unit 51.

The multi-stack film 14 which is formed so as to surround the outer trench 12B is configured as the outer frame 14W. The multi-stack film 14 in a region that is surrounded by the outer trench 12B includes an inner frame 14U and supporters 14S.

The inner frame 14U is formed along an inner circumference 12c of the outer trench 12B.

In a region surrounded by the inner frame 14U, plural strip-shaped supporters 14S are formed. The supporters 14S are arranged at regular intervals in the Y direction so as to extend in a direction parallel to the X direction.

The supporters 14S are arranged in contact with the openings 12A.

The supporters 14S extend up to the ends of the memory cell region, and each end of the supporters 14S is connected to the inner frame 14U.

The layout of the supporters 14S shown in FIG. 2 is an example, and the shape, number, extending direction, and position of the supporters 14S are not limited to this.

The supporters 14S may only need to overlap with the individual openings 12A at least in a partial region thereof. Moreover, the supporters 14S may be patterned so that the contact positions and regions thereof are different in the individual openings 12A.

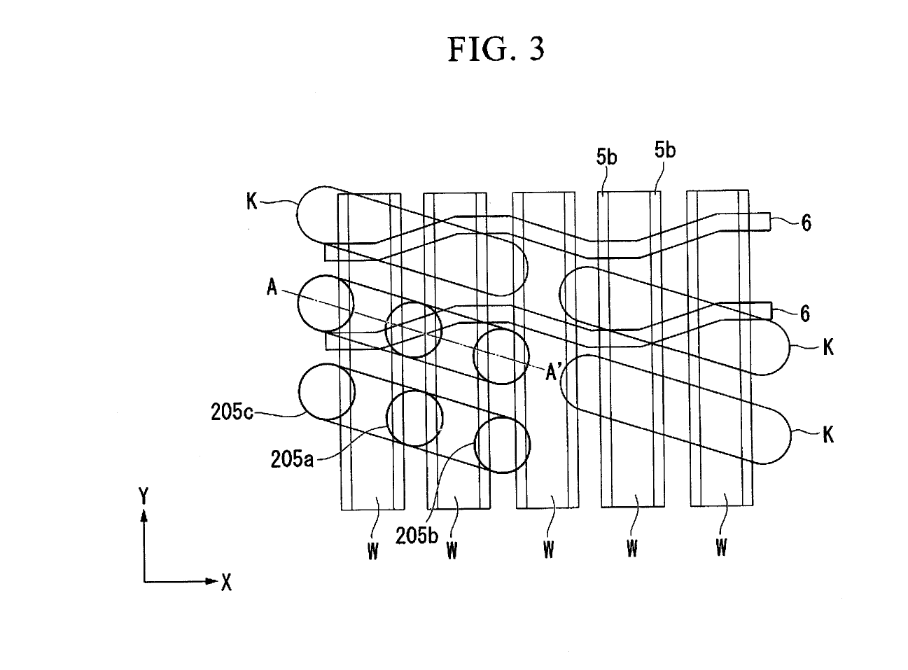

FIG. 3 is a conceptual enlarged top-view diagram of the memory cell unit shown in FIG. 2. In this figure, active regions K, bit lines 6, and substrate contacts 205a to 205c are projected on the top view of the sections of word lines W. A memory cell is formed within the memory cell unit 51, and FIG. 3 shows an example of a top-view structure of the memory cell.

FIG. 3 shows only some of the constituent elements of the memory cell, and illustrations of the capacitor element Ca and other elements are omitted. The line A-A′ in FIG. 3 corresponds to the line A-A′ in FIG. 2.

As shown in FIG. 3, the word lines W are formed in a strip-shaped pattern extending in a direction parallel to the Y direction and are arranged in regular intervals in the X direction. The word lines W are gate electrodes 5 each being formed with sidewalls 5b.

The bit lines 6 are formed in a pattern extending in a bent line shape (curved shape) in the X direction and are arranged at regular intervals in the Y direction. The active regions K are long rectangular regions formed so as to extend obliquely downward in the X direction as the horizontal direction and are arranged at regular intervals in the X and Y directions.

The substrate contacts 205a to 205c are circular portions in top view which are formed at both ends and the center of each of the active regions K. The centers of the substrate contacts 205a to 205c are defined between the word lines W.

The shape, number, and position of the active regions K shown in FIG. 3 are exemplary and are not limited to this. For example, the active regions K may have the shape of the active region applied to general transistors.

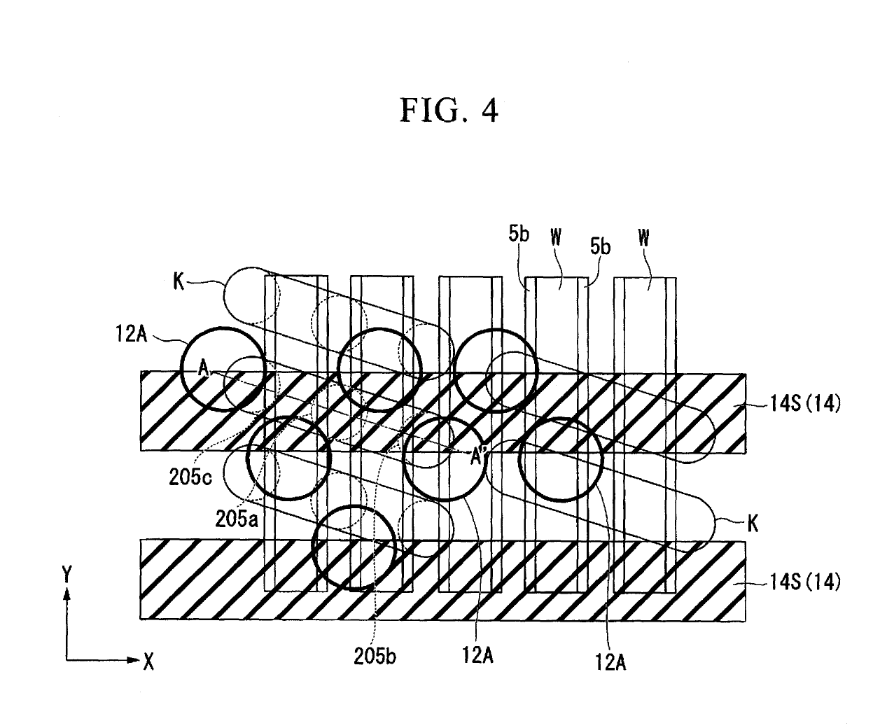

FIG. 4 is another conceptual enlarged top view of the memory cell unit shown in FIG. 2.

In FIG. 4, illustrations of the bit lines 6 are omitted from the top-view structure shown in FIG. 3, and the formation positions 12A of the bottom electrodes of the capacitor elements are illustrated.

As shown in FIG. 4, plural word lines W each being formed with the sidewalls 5b are depicted as a strip-shaped pattern extending in a direction parallel to the Y direction.

The supporters 14S shown in FIG. 4 are depicted as a strip-shaped pattern extending in the X direction, which is an example of the pattern of the supporters 14S formed by being transferred from a photomask.

When the openings 12A for the bottom electrodes are formed after the multi-stack film 14 is formed on the interlayer insulating film, the multi-stack film 14 will not be present in the openings 12A. Therefore, the supporters 14S which are finally formed by being transferred from a photomask will remain only in regions which are disposed outside the openings 12A as shown in FIG. 2.

On the other hand, when the multi-stack film 14 is formed after the openings 12A for the bottom electrodes are formed, the multi-stack film 14 will be formed in the openings 12A. In this case, the supporters 14S which are finally formed by being transferred from a photomask will remain in the openings 12A as the multi-stack film 14 as shown in FIG. 4.

In the active region K including the line A-A′ in FIG. 4, the openings 12A are defined so as to overlap with the substrate contacts 205b and 205c. The size of the circles representing the openings 12A is set to be twice the size of the circles representing the substrate contacts 205a to 205c.

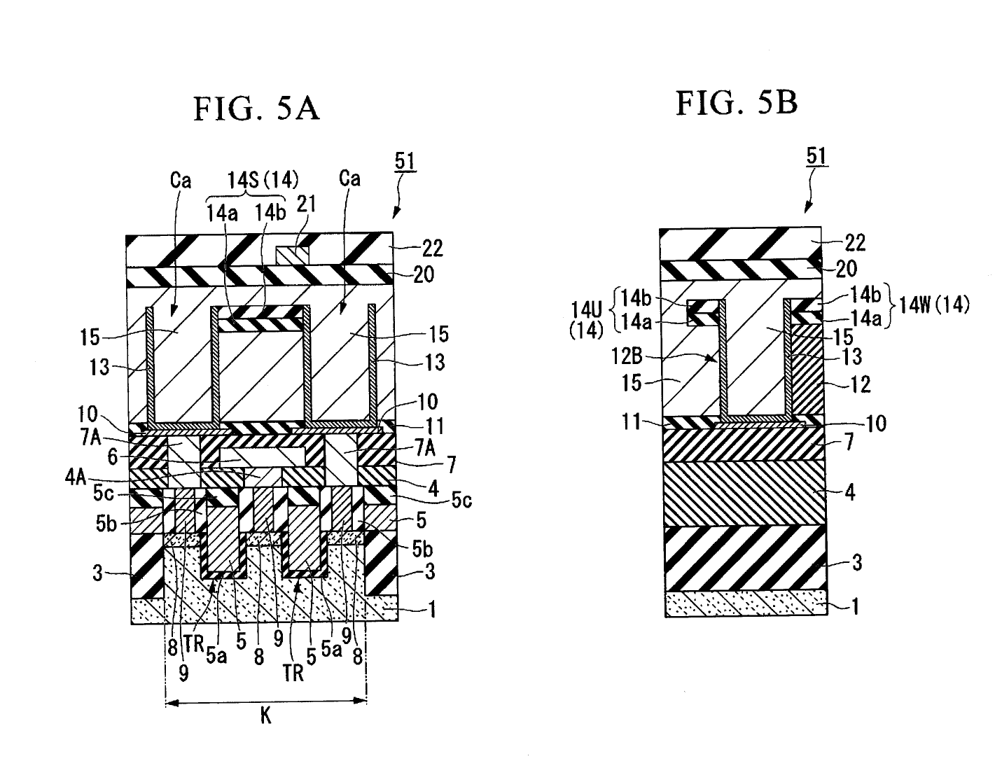

FIGS. 5A and 5B are schematic views showing an example of the memory cell unit shown in FIG. 2. FIG. 5A is a cross-sectional view along the line A-A′ in FIG. 2, and FIG. 5B is a cross-sectional view along the line B-B′ in FIG. 2.

As shown in FIG. 5A, the memory cell unit 51 of the semiconductor device 50 according to an embodiment of the invention includes a semiconductor substrate 1, MOS transistors TR formed on the semiconductor substrate 1, and capacitance elements (hereinafter referred to as capacitor elements) connected to the MOS transistors TR.

As shown in FIG. 5A, trenches are formed on one surface of the semiconductor substrate 1, and an insulating film such as a silicon oxide film (SiO₂) is filled in the trenches, whereby device separation regions 3 are formed. The semiconductor substrate 1 is a silicon (Si) substrate containing P-type impurities having a certain concentration.

The device separation regions 3 can be formed by a shallow trench isolation (STI) method. However, the forming method of the device separation regions 3 is not limited to the STI method, but may be formed by methods other than the STI method.

A region surrounded by the device separation regions 3 is configured as the active region K. The device separation regions 3 isolate and separate the adjacent active regions K.

Trenches different from the device separation regions 3 are formed on the surface of the semiconductor substrate 1 in the active region K. Trench gate electrodes 5 are formed so as to fill the trenches and protrude from the semiconductor substrate 1.

The gate electrodes 5 are formed from a multi-stack film that includes an impurity-containing polycrystalline silicon film and a metal film.

The polycrystalline silicon film is formed, for example, by a chemical vapor deposition (CVD) method, and impurities such as phosphorus (P) can be included therein during the deposition. Alternatively, N or P-type impurities may be introduced into the polycrystalline silicon film by an ion implantation method after the polycrystalline silicon film is deposited without including impurities therein.

As the metal film, high-melting-point metals such as tungsten (W), tungsten nitride (WN), or tungsten silicide (WSi) can be used, for example.

On the top side of the semiconductor substrate 1 in the active region K, N-type impurities such as phosphorus (P) are introduced, and an impurity diffusion layer 8 is formed. The impurity diffusion layer 8 functions as the source/drain regions of the MOS transistor TR.

The MOS transistor TR includes two trench gate electrodes 5 disposed in one active region K. Thus, the MOS transistor TR has a cell structure in which a 2-bit memory cell is disposed in one active region K.

The MOS transistor TR is not limited to the structure shown in FIG. 5A, but a planar MOS transistor, a MOS transistor in which a channel region is formed on the side surfaces of a trench provided to the semiconductor substrate 1, and a vertical MOS transistor may be used.

The impurity diffusion layer 8 is partitioned by the gate electrodes 5 and formed at three portions, namely both ends and the center of the active region K. The respective positions of the three formation portions of the impurity diffusion layer 8 correspond to the positions of the substrate contacts 205a, 205b, and 205c shown in FIG. 3.

A gate insulating film 5a such as a silicon oxide film is formed between the gate electrodes 5 and the semiconductor substrate 1.

A sidewall 5b formed from an insulating film such as a silicon nitride film (Si₃N₄) is formed on the lateral walls of each of the gate electrodes 5 protruding upward from the semiconductor substrate 1.

A cap layer 5c formed from a silicon nitride film or the like is formed so as to cover the upper surfaces of the gate electrodes 5. The cap layer 5c is also formed on the upper surfaces of the gate electrodes 5 disposed on the device separation regions 3.

Although not shown in FIG. 5A, a gate interlayer insulating film 40 formed from silicon oxide or the like is formed so as to fill a space between the gate electrodes 5. In FIG. 5B, the illustration of the gate interlayer insulating film 40 is omitted by being integrated with a first interlayer insulating film 4.

As shown in FIG. 5A, substrate contact plugs 9 are formed on the respective three impurity diffusion layers 8. The substrate contact plugs 9 are disposed at the positions of the substrate contacts 205c, 205a, and 205b shown in FIG. 3.

The substrate contact plugs 9 have a self-aligned structure, the width of each substrate contact plug 9 in the X direction corresponds to the distance between the sidewalls 5b disposed between the adjacent word lines W.

The substrate contact plugs 9 are formed from polycrystalline silicon containing phosphorus (P), for example.

As shown in FIG. 5A, the first interlayer insulating film 4 is formed so as to cover the sidewalls 5b, the cap layer 5, and the substrate contact plugs 9.

A contact hole is provided so as to penetrate through the first interlayer insulating film 4 and be disposed above the substrate contact 205a. A bit-line contact plug 4A is formed so as to fill the contact hole and be electrically connected to the substrate contact plug 9.

The bit-line contact plug 4A is formed, for example, by laminating tungsten (W) on a barrier film (TiN/Ti) which is formed from a multi-stack film of titanium (Ti) and titanium nitride (TiN).

The bit lines 6 are formed to be connected to the bit-line contact plug 4A. The bit lines 6 are multi-stack films formed from tungsten nitride (WN) and tungsten (W). A second interlayer insulating film (insulating film) 7 is formed so as to cover the bit lines 6.

Contact holes are provided so as to penetrate through the first and second interlayer insulating films 4 and 7 to be positioned at the substrate contacts 205b and 205c. Capacitor contact plugs 7A are formed so as to fill the contact holes and be connected to the substrate contact plugs 9.

Capacitor contact pads 10 are disposed on the second interlayer insulating film 7 so as to be electrically connected to the capacitor contact plugs 7A. The capacitor contact pads 10 are multi-stack films formed from tungsten nitride (WN) and tungsten (W), for example. The capacitor contact plugs 7A and the capacitor contact pads 10 function as connection electrodes that connect MOS transistors and electrodes (bottom electrodes) of capacitor elements.

A third interlayer insulating film 11 formed from a silicon nitride film is formed so as to cover the capacitor contact pads 10. The silicon nitride film of the third interlayer insulating film 11 may be a single-layer film and a deposition method thereof is not particularly limited as long as the film has chemical resistance to hydrofluoric acid.

A structure is also possible in which the capacitor contact pads 10 are not provided and the capacitor contact plugs 7A are directly connected to the electrodes (bottom electrodes) of the capacitor elements. In this case, the third interlayer insulating film 11 is formed so as to cover the upper surfaces of the capacitor contact plugs 7A.

As shown in FIG. 5A, the capacitor elements Ca each include a bottom electrode 13, a capacitor insulating film (not shown) that is formed so as to cover one surface of the bottom electrode 13, and a top electrode 15 that is formed so as to interpose the capacitor insulating film between the bottom electrode 13 and the top electrode 15.

The bottom electrodes 13 of the capacitor elements Ca have a cylindrical shape (crown shape) with one closed end. The closed end surfaces penetrate through the third interlayer insulating film 11 so as to be connected to the capacitor contact pads 10. Thus, electrical connection between the bottom electrodes 13 and the capacitor contact pads 10 is ensured.

Although not shown in the figure, the capacitor insulating film is formed on the outer wall surfaces of each of the bottom electrodes 13. However, the invention is not limited to this structure, and the capacitor insulating film may be formed on the inner wall surfaces of each of the bottom electrodes 13. In this manner, by forming the bottom electrode 13 in a cylindrical shape, the inner wall surfaces of each of the bottom electrodes 13 can be used for securing the electrostatic capacitance of the capacitor.

The shape of the bottom electrodes 13 of the capacitors is not limited to a cylindrical shape but may be a pillar shape (columnar shape) in which the inside of the openings 12A are completely filled with the materials for the bottom electrodes 13.

In the case of the pillar-shaped bottom electrodes 13, by forming the supporters 14S from the stress-relaxed multi-stack film 14 so as to connect the respective bottom electrodes 13, it is possible to prevent collapse of the bottom electrodes 13.

The upper ends of two bottom electrodes 13 are connected by the supporter 14S. The supporter 14S is the multi-stack film 14 obtained by laminating a second support film 14b on a first support film 14a. In this manner, since the bottom electrodes 13 are connected by the supporters 14S, even when the outer wall surfaces of the bottom electrodes 13 are exposed during the manufacturing process of the capacitor, it is possible to prevent collapse of the bottom electrodes 13.

The supporter 14S is preferably the multi-stack film 14 in which the first and second support films 14a and 14b are stacked. Any one of the first and second support films 14a and 14b may be stacked first. In this embodiment, although the multi-stack film 14 obtained by laminating the second support film 14b on the first support film 14a is used as the supporter 14S, the first support film 14a may be stacked on the second support film 14b.

The first support film 14a has a compressive stress, and the second support film 14b has a tensile stress. Therefore, in either case, the stresses of the first and second support films 14a and 14b are balanced, and the stress of the supporters 14S can be relaxed. Thus, the occurrence of cracks resulting from the stress can be prevented. Accordingly, it is possible to prevent collapse of the supporters 14S and accordingly collapse of the bottom electrodes 13.

The supporters 14S preferably have chemical resistance to hydrofluoric acid. This is because the supporters 14S are also exposed to hydrofluoric acid when etching is performed using hydrofluoric acid so as to expose the wall surfaces of the bottom electrodes 13 during the manufacturing process of the capacitor.

As the first and second support films 14a and 14b that constitute the multi-stack film 14, a silicon nitride film can be used, for example. However, the invention is not limited to the silicon nitride film, and an insulating film other than the silicon nitride film may be used.

The silicon nitride film has a stress in any of the compressive and tensile directions in accordance with a deposition method as well as chemical resistance to hydrofluoric acid. Therefore, for example, a silicon nitride film formed by a high density plasma chemical vapor deposition (hereinafter referred to as HDP-CVD) method can be used as the first support film 14a. Moreover, a silicon nitride film formed by an atomic layer deposition (hereinafter referred to as ALD) method can be used as the second support film 14b.

The silicon nitride film formed by the HDP-CVD method has a compressive stress, and the silicon nitride film formed by the ALD method has a tensile stress. Therefore, a multi-stack film including these films will have a relaxed stress.

Instead of the silicon nitride film formed by the ALD method, a silicon nitride film formed by a low pressure chemical vapor deposition (LP-CVD) method may be used. The silicon nitride film formed by the LP-CVD method also has a tensile stress and chemical resistance to hydrofluoric acid.

The use of the ALD method enables the silicon nitride film to be formed at a lower temperature than the LP-CVD method. Thus, the ALD method is preferred when it is desired to reduce thermal hysteresis applied to a DRAM device.

The multi-stack film 14 that constitutes the supporter 14S is not limited to a two-layer structure but may be a multilayer structure having three or more layers. When the multi-stack film 14 has a multilayer structure having three or more layers, preferably, the first and second support films 14a and 14b are stacked alternately. By doing so, the stresses of the first and second support films 14a and 14b are balanced more effectively, and the stress of the supporters 14S can be relaxed. Thus, the occurrence of cracks resulting from the stress can be prevented. Accordingly, it is possible to prevent collapse of the supporters 14S and accordingly collapse of the bottom electrodes 13.

For example, a three-layer structure is possible in which the first support film 14a, the second support film 14b, and the first support film 14a are stacked in that order from the substrate side. This three-layer structure will be also referred to as a 3-layer structure including the first support film 14a, the second support film 14b, and the first support film 14a. Moreover, a three-layer structure including the second support film 14b, the first support film 14a, and the second support film 14b is also possible. Furthermore, a four-layer structure including the first support film 14a, the second support film 14b, the first support film 14a, and the second support film 14b and a four-layer structure including the first support film 14a, the second support film 14b, the first support film 14a, and the first support film 14a are also possible.

For example, the 3-layer structure including the first support film 14a, the second support film 14, and the first support film 14a is formed by the multi-stack film 14 having a three-layer structure including, from the substrate side, a silicon nitride film formed by the HDP-CVD method, a silicon nitride film formed by the ALD method, and a silicon nitride film formed by the HDP-CVD method.

The thicknesses of the first and second support films 14a and 14b are not particularly limited, and they may be the same and may be different. The respective film thicknesses and deposition conditions are adjusted so that the stress of the multi-stack film 14 is best relaxed.

On the third interlayer insulating film 11, the top electrode 15 is formed so as to cover the bottom electrodes 13 and the supporters 14S and fill the voids.

The capacitor insulating film (not shown) is provided between the bottom electrodes 13 and the top electrode 15. In this way, the capacitor element Ca having the bottom electrode 13, the top electrode 15, and the capacitor insulating film is formed.

As shown in FIG. 5B, on the peripheral side of the memory cell unit 51, a fourth interlayer insulating film 12 formed from a silicon oxide film or the like is formed on the third interlayer insulating film 11. The bottom electrode 13 is formed so as to be in contact with the fourth interlayer insulating film 12, and the bottom electrode 13 is connected to the capacitor contact pad 10. The bottom electrode 13 is formed so as to fill the outer trench 12B which is provided so as to expose the capacitor contact pad 10.

The upper end of the bottom electrode 13 in the outer trench 12B is connected to the outer frame 14W and the inner frame 14U which are formed from the multi-stack film 14.

As shown in FIG. 2, the supporter 14S is connected to the inner frame 14U, and the inner frame 14U is connected to the bottom electrode 13 which is secured by the fourth interlayer insulating film 12. Therefore, the supporter 14S is strongly supported, and even when the wall surfaces of the bottom electrode 13 are exposed during the manufacturing process of the capacitor, the bottom electrode 13 will not collapse.

As shown in FIGS. SA and 5B, a fifth interlayer insulating film 20 is formed so as to cover the top electrode 15.

A wiring layer 21 formed from aluminum (Al), copper (Cu), or the like is formed on the fifth interlayer insulating film 20.

Furthermore, a surface protection film 22 is formed so as to cover the fifth interlayer insulating film 20 and the wiring layer 21.

With the above-described configuration, the semiconductor device 50 according to an embodiment of the invention is formed.

### Manufacturing Method of Semiconductor Device:

Next, a manufacturing method of a semiconductor device according to an embodiment of the present invention will be described.

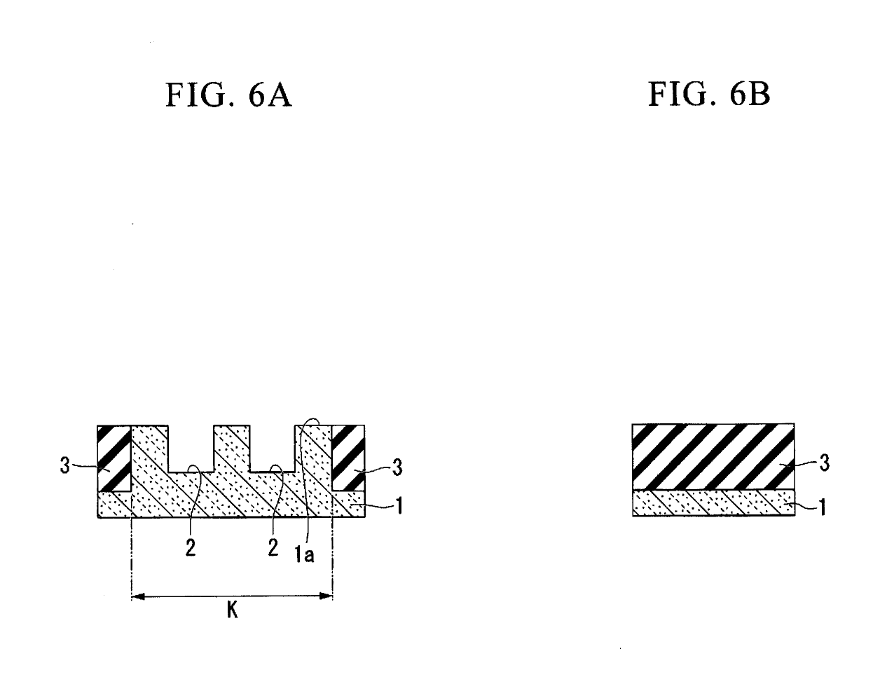

FIGS. 6A and 6B to FIGS. 14A and 14B are cross-sectional process diagrams showing an example of a manufacturing method of the semiconductor device 50 according to an embodiment of the present invention. FIGS. 6A to 14A are schematic cross-sectional views along the line A-A′ in FIG. 2, and FIGS. 6B to 14B are schematic cross-sectional views along the line B-B′ in FIG. 2. Unless otherwise noted, the manufacturing process for the memory cell and the peripheral region of the memory cell unit 51 will be described simultaneously with reference to FIGS. 6A and 6B to FIGS. 14A and 14B.

First, trenches are formed on one surface (principal surface) 1a of a semiconductor substrate 1 formed from P-type silicon by the STI method. After that, an insulating film of silicon oxide (SiO₂) or the like is filled in the trenches, whereby device separation regions 3 are formed. The position and size of the device separation regions 3 are appropriately set to comply with the position and size of the active region K.

Subsequently, as shown in FIGS. 6A and 6B, trenches 2 for the gate electrodes 5 of the MOS transistor TR are formed in the active region K partitioned by the device separation regions 3. The trenches 2 are formed, for example, by etching the silicon in the semiconductor substrate 1 using a photoresist pattern (not shown) as a mask.

Subsequently, the surface of the silicon in the semiconductor substrate 1 is oxidized by a thermal oxidation method, whereby a thermal oxidation film formed from silicon oxide having a thickness of about 4 nm is formed.

The thermal oxidation film formed on the inner wall surfaces of the trenches 2 serves as a gate insulating film 5a.

As the gate insulating film 5a, a multi-stack film of silicon oxide and silicon nitride, a high-K film (high dielectric film), or the like may be used.

After that, by the CVD method using monosilane (SiH₄) and phosphine (PH₃) as the raw material gas, a polycrystalline silicon film containing N-type impurities such as phosphorus is deposited to a thickness such that the insides of the trenches 2 are completely filled with the polycrystalline silicon film.

At that time, desired impurities may be introduced into the polycrystalline silicon film by the ion implantation method after the polycrystalline silicon film without impurities is formed.

Subsequently, a metal film is deposited to a thickness of about 50 nm on the polycrystalline silicon film by the sputtering method. As the metal film, high-melting-point metals such as tungsten, tungsten nitride, or tungsten silicide can be used.

The multi-layer film formed from the polycrystalline silicon film and the metal film serves as the gate electrode 5.

Subsequently, by the plasma CVD method using monosilane and ammonia (NH₃) as the raw material gas, a cap layer 5c formed from an insulating film such as silicon nitride is deposited to a thickness of about 70 nm on the metal film.

After that, after a photoresist (not shown) is deposited on the cap layer 5c, a photoresist pattern for forming the gate electrodes 5 is formed using a mask by a photolithography method. Then, the cap layer 5c is etched using the photoresist pattern as a mask.

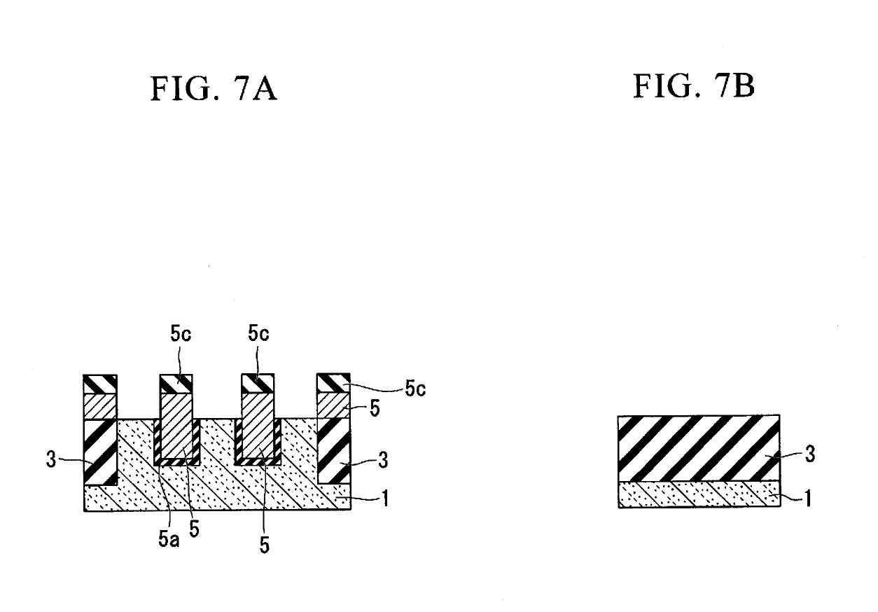

Subsequently, after the photoresist pattern is removed, the metal film and the polycrystalline silicon film are etched using the cap layer 5c as a hard mask, whereby the gate electrodes 5 are formed as shown in FIGS. 7A and 7B. The cap layer 5c is formed on the upper surface of the gate electrode 5.

After that, phosphorus (P) serving as an N-type impurity is ion-implanted to the principal surface 1a of the semiconductor substrate 1 in the active region K, whereby an impurity diffusion layer 8 is formed.

Subsequently, by the CVD method, a silicon nitride film is deposited to a thickness of about 20 to 50 nm so as to cover the principal surface 1a of the semiconductor substrate 1.

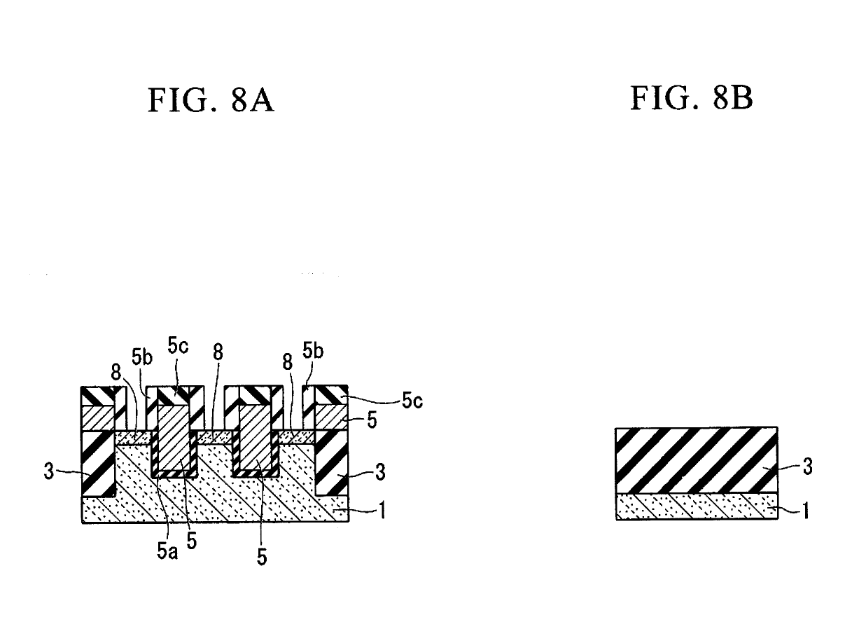

After that, the silicon nitride film is etched back, whereby sidewalls 5b are formed so as to cover the lateral walls of the gate electrodes 5 as shown in FIGS. 8A and 8B.

Subsequently, by the CVD method, a gate interlayer insulating film 40 formed from silicon oxide or the like is formed so as to cover the cap layer 5c and the sidewalls 5b.

After that, by the chemical mechanical polishing (CMP) method, the surface of the gate interlayer insulating film 40 is polished until the upper surface of the cap layer 5c is exposed, whereby unevenness resulting from the gate electrodes 5 is planarized.

Subsequently, a mask formed from a photoresist pattern is formed so as to form openings at the positions of the substrate contacts 205a, 205b, and 205c, and etching is carried out. The openings are provided between the gate electrodes 5 by self-alignment using the cap layer 5c and the sidewalls 5b.

After that, a phosphorus-containing polycrystalline silicon film is deposited onto the principal surface 1a of the semiconductor substrate 1 by the CVD method. Then, the surface of the polycrystalline silicon film is polished by the CMP method until the surface of the cap layer 5c is exposed. In this way, substrate contact plugs 9 formed from the polycrystalline silicon film filled in the openings are formed.

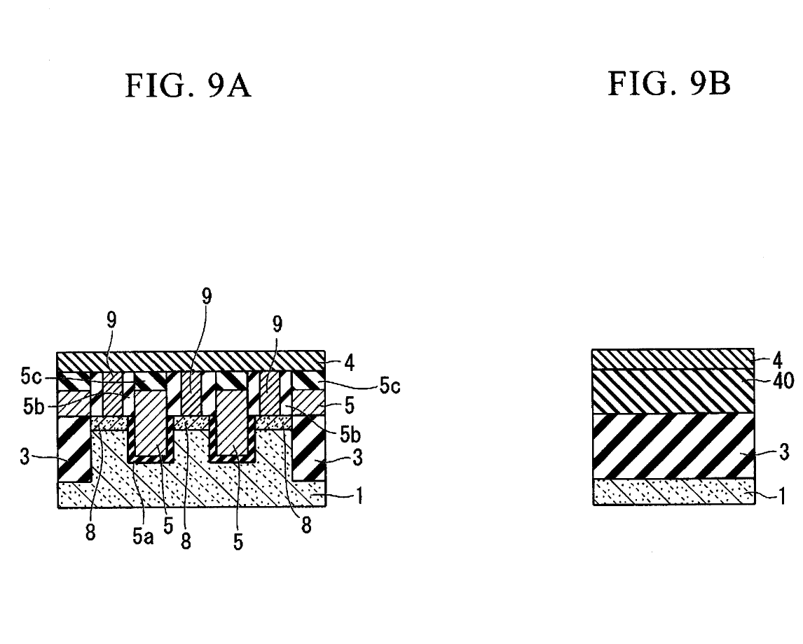

Subsequently, as shown in FIGS. 9A and 9B, by the CVD method, a first interlayer insulating film 4 formed from silicon oxide is formed to a thickness of about 600 nm, for example, so as to cover the cap layer 5c, the sidewalls 5b, the substrate contact plugs 9, and the gate interlayer insulating film 40.

After that, the first interlayer insulating film 4 is polished by the CMP method so that the thickness after polishing becomes 300 nm, for example.

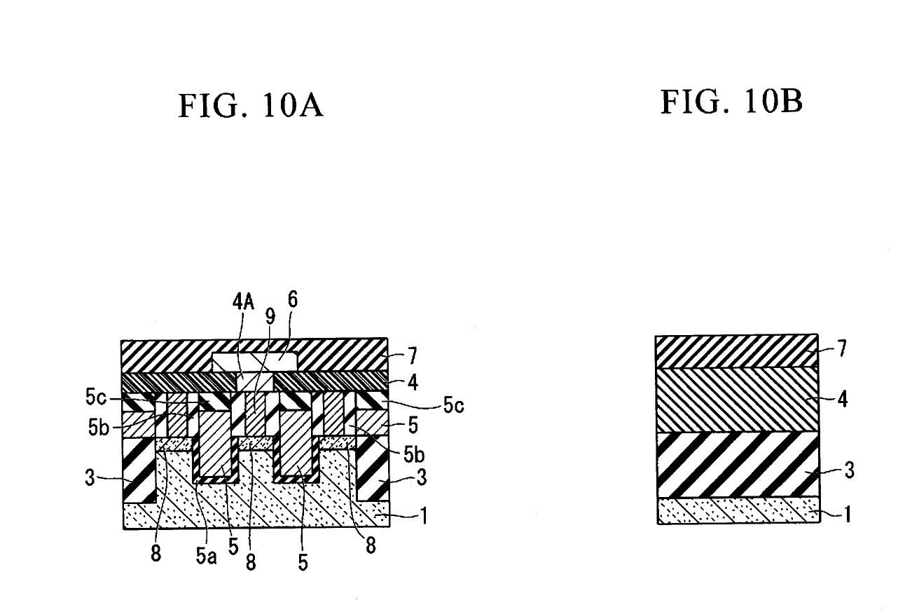

The gate interlayer insulating film 40 and the first interlayer insulating film 4 are formed from the same material. Therefore, in the description of the figures subsequent to FIGS. 10A and 10B, the gate interlayer insulating film 40 and the first interlayer insulating film 4 will be described as the first interlayer insulating film 4.

Subsequently, a contact hole that penetrates through the first interlayer insulating film 4 is formed at the position of the substrate contact 205a so as to expose the surface of the substrate contact plug 9. Then, a multi-stack film obtained by depositing tungsten (W) on a barrier film of TiN/Ti or the like is formed so as to fill the contact hole. After that, the surface of the multi-stack film is polished by the CMP method, and the multi-stack film is used as a bit-line contact plug 4A.

Subsequently, a bit line 6 is formed on the first interlayer insulating film 4 so as to be connected to the bit-line contact plug 4A.

After that, as shown in FIGS. 10A and 10B, a second interlayer insulating film 7 formed from silicon oxide or the like is formed so as to cover the bit line 6 and the first interlayer insulating film 4.

Subsequently, contact holes that penetrate through the first and second interlayer insulating films 4 and 7 are formed at the positions of the substrate contacts 205b and 205c in FIG. 3 so as to expose the surfaces of the substrate contact plugs 9. Then, multi-stack films obtained by laminating tungsten (W) on a barrier film of TiN/Ti or the like are formed so as to fill these contact holes.

After that, the surfaces of the multi-stack films are polished by the CMP method, and the multi-stack films are used as capacitor contact plugs 7A.

Subsequently, capacitor contact pads 10 formed from a multi-stack film including tungsten are formed on the second interlayer insulating film 7 so as to be connected to the capacitor contact plugs 7A. In this way, electrical connection between the capacitor contact plugs 7A and the capacitor contact pads 10 is ensured. The sizes of the capacitor contact pads 10 are set so as to be larger than the size of the bottom of the bottom electrode of a capacitor element which is formed in a later process.

Moreover, in the peripheral region of the memory cell unit 51, the capacitor contact pad 10 is formed at the position where the outer trench 12B is formed in a later process.

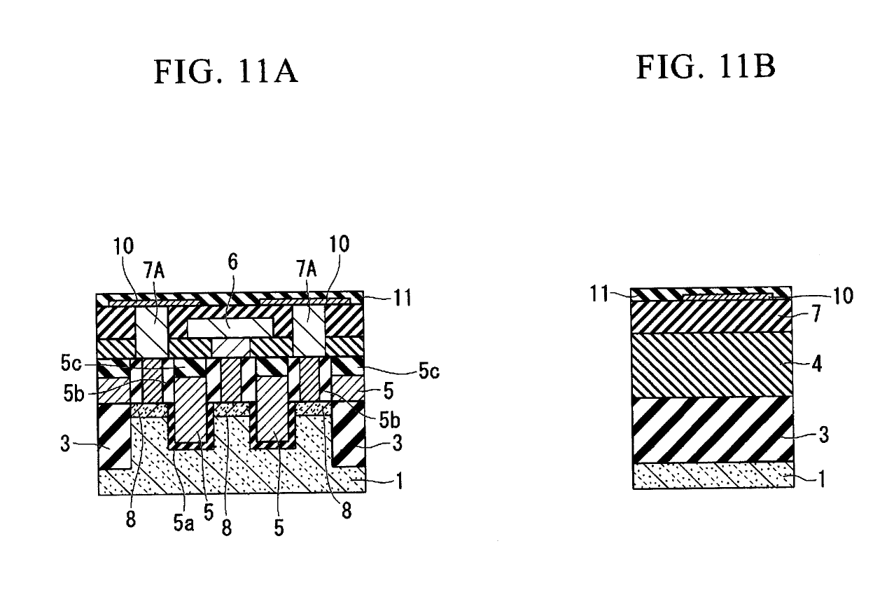

After that, as shown in FIGS. 11A and 11B, a third interlayer insulating film 11 formed from silicon nitride is deposited to a thickness of 60 nm, for example, so as to cover the capacitor contact pads 10 and the second interlayer insulating film 7.

Subsequently, a fourth interlayer insulating film 12 formed from silicon oxide or the like is deposited to a thickness of 2 μm, for example, so as to cover the third interlayer insulating film 11.

After that, a first support film 14a formed from silicon nitride film is deposited by the HDP-CVD method so as to cover the fourth interlayer insulating film 12 in a manner described below. The thickness of the first support film 14a formed from the silicon nitride film is set to be about 50 nm, for example.

Deposition of Silicon Nitride Film using HDP-CVD Method:

First, semiconductor substrates 1 subjected to deposition are mounted one by one on a stage provided in a chamber (reaction chamber) of a HDP-CVD deposition apparatus. The temperature of the semiconductor substrate 1 mounted on the stage is adjusted to be in a range of 450 to 500° C.

Subsequently, the raw material gas is supplied into the chamber, and the inside of the chamber is maintained to be at a predetermined degree of vacuum by a vacuum pump. Silane (SiH₄) gas and nitrogen (N₂) gas are used as the raw material gas, and inert gas such as argon (Ar) is used as carrier gas. For example, the flow rate of SiH₄ gas is set to 150 sccm to 250 sccm, and the flow rate of N₂ gas is set to 200 to 300 sccm.

After that, a high-frequency power (hereinafter referred to as a source power) is supplied from an RF generator to coils arranged so as to surround the chamber, whereby inductively coupled plasma is generated in the chamber. The source power is set to 7500 W to 12000 W.

A high-frequency power (hereinafter referred to as a bias power) for independent control is added to the stage mounting the semiconductor substrate 1 thereon from an RF generator provided separately. The bias power is set to 500 to 1500 W.

In this manner, plasma is generated in the chamber of the HDP-CVD deposition apparatus. At that time, the source power and the bias power are controlled independently so as to control the movement of ions contributing to deposition and regulate the state of a deposited film.

By performing the HDP-CVD method under such conditions, a silicon nitride film having a predetermined compressive stress can be formed. Moreover, the silicon nitride film formed by the HDP-CVD method has chemical resistance to hydrofluoric acid.

Subsequently, a second support film 14b formed from silicon nitride is deposited by the ALD method so as to cover the first support film 14a in the manner described below.

The thickness of the second support film 14b formed from the silicon nitride is set to be about 50 nm, for example.

### Deposition of Silicon Nitride Film Using ALD Method:

First, plural semiconductor substrates 1 subjected to deposition are accommodated to be spaced by a predetermined distance in a process tube (reaction chamber) of an ALD deposition apparatus. As the ALD deposition apparatus, a batch-type vertical hot-wall apparatus capable of simultaneously processing plural semiconductor substrates can be used. Electrodes are provided in the ALD deposition apparatus, and by supplying a high-frequency power to the electrodes from an RF generator, nitrogen raw material gas in a plasma state can be supplied.

Subsequently, the inside of the process tube is maintained to be at a predetermined degree of vacuum by a vacuum pump, and the temperature of the semiconductor substrates 1 accommodated in the process tube is adjusted to be in a range of 400° C. to 650° C.

After that, silicon raw material gas is supplied so that a silicon film corresponding to approximately one layer of silicon atoms is adsorbed onto the semiconductor substrate 1 (hereinafter referred to as first ALD process). For example, dichlorosilane (SiH₂Cl₂) gas is used as the silicon raw material gas and supplied at a flow rate of 1 slm to 3 slm for a predetermined period of time.

Subsequently, nitrogen raw material gas is supplied while stopping the supply of silicon raw material gas so as to nitride the adsorbed silicon film with the plasma nitrogen raw material gas, whereby a silicon nitride film is formed (hereinafter referred to as a second ALD process). For example, ammonia (NH₃) gas is used as the nitrogen raw material gas and supplied at a flow rate of 4 slm to 6 slm for a predetermined period of time.

The first and second ALD processes are repeated alternately, whereby a silicon nitride having a desired thickness is deposited.

During the first and second ALD processes, purge gas such as nitrogen (N₂) gas is supplied so as to discharge remaining gas out of the process tube.

The respective raw material gases may be supplied in a diluted state using inert gas.

By performing the ALD method under such conditions, a silicon nitride film having a tensile stress can be formed. Moreover, the silicon nitride film formed by the ALD method has chemical resistance to hydrofluoric acid.

The absolute stresses of the respective silicon nitride films can be adjusted to some extent in accordance with the deposition condition and film-thickness change. However, it is not necessary to make the absolute stresses of the respective silicon nitride films identical to each other.

In this way, the multi-stack film 14 having a thickness of about 100 nm is formed. The multi-stack film 14 includes the first and second support films 14a and 14b, and the first and second support films 14a and 14b have stress characteristics in opposite directions. Therefore, the overall stress of the multi-stack film 14 can be relaxed. Since the stress of the multi-stack film 14 is relaxed, no cracks will be formed in the supporter 14S.

Subsequently, openings are formed at the formation positions 12A of the bottom electrodes of the capacitor elements by anisotropic dry-etching so as to expose the surfaces of the capacitor contact pads 10. At the same time, an outer trench 12B is formed along the periphery of the memory cell unit 51 so as to expose the surfaces of the capacitor contact pads 10.

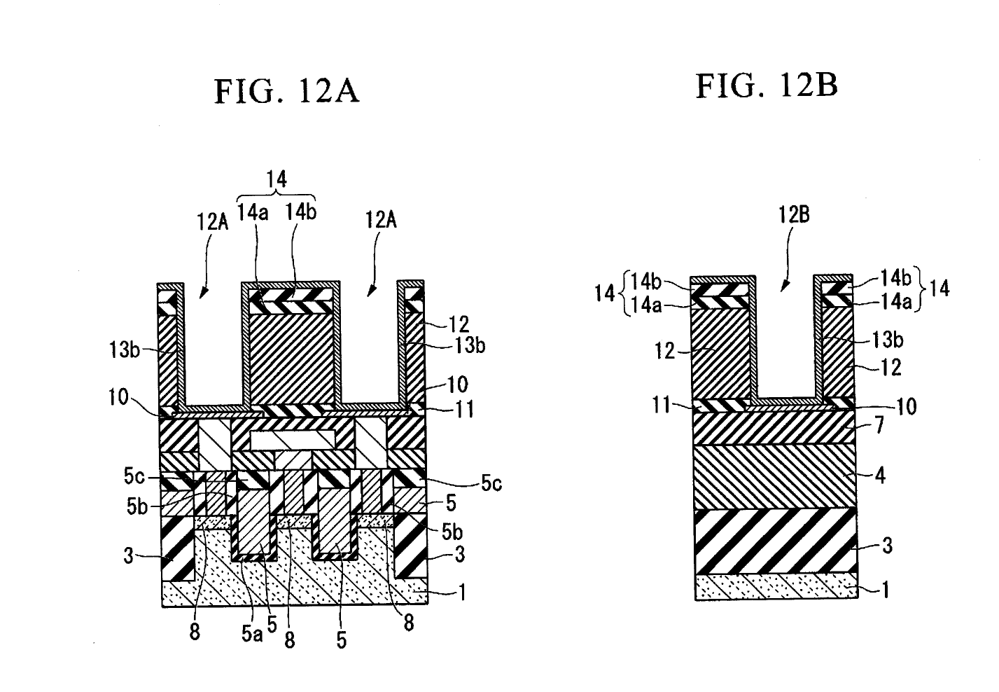

After that, as shown in FIGS. 12A and 12B, a conductive film 13b formed from a titanium nitride film is formed so as to cover the surface of the multi-stack film 14 and the inner surfaces of the openings 12A and the outer trench 12B. As the conductive film 13b, a metal film other than the titanium nitride may also be used.

Subsequently, a protection film 13a formed from a silicon oxide film or the like is formed so as to fill the insides of the openings 12A and the outer trench 12B, in which the conductive film 13b is formed, and cover the multi-stack film 14. The protection film 13a is a film for protecting the conductive film 13b of the bottom electrodes at the time of patterning the multi-stack film 14.

After that, the surface of the protection film 13a is polished by the CMP method until the conductive film 13b is exposed. Furthermore, the surfaces of the conductive film 13b and the protection film 13a are polished by the same method, and the conductive film 13b remaining after polishing is used as the bottom electrodes 13.

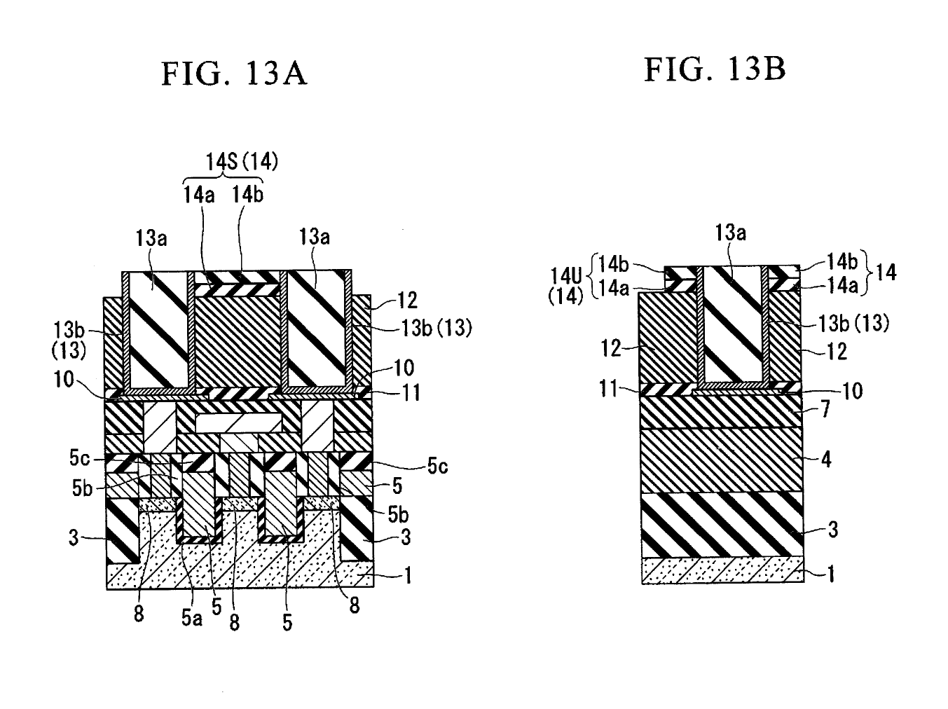

Subsequently, the multi-stack film 14 is subjected to patterning using a photoresist pattern as a mask. The multi-stack film 14 is patterned into a supporter 14S, an inner frame 14U, and an outer frame 14W as shown in FIGS. 13A and 13B.

The supporter 14S connects the bottom electrodes 13. Moreover, the supporter 14S is connected to the inner frame 14U which is formed so as to be in contact with the upper ends of the lateral surfaces of each of the bottom electrodes 13.

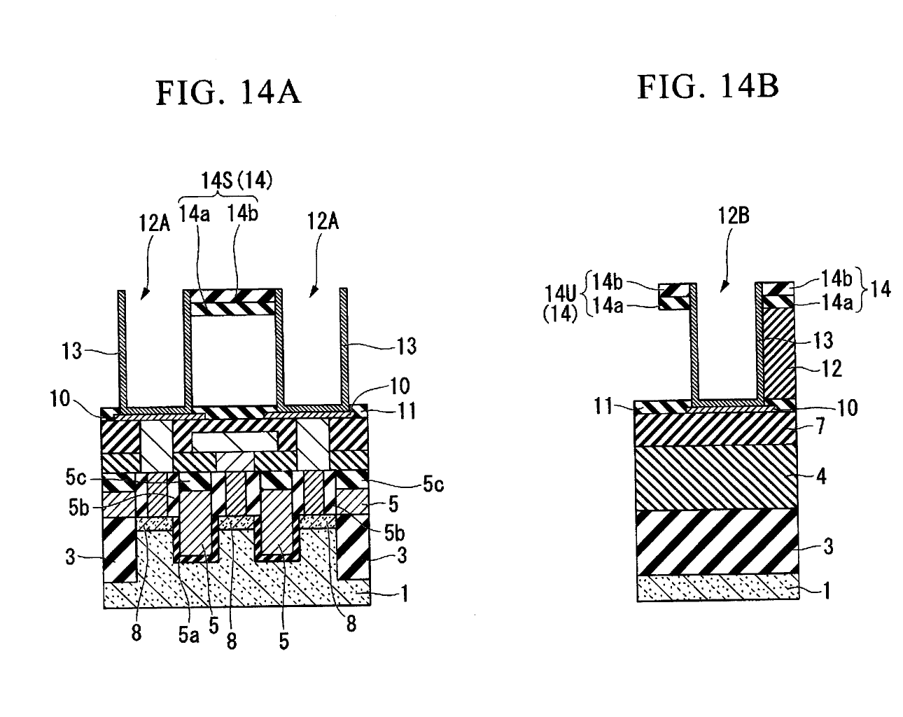

After that, as shown in FIGS. 14A and 14B, wet-etching process is performed using a chemical solution containing hydrofluoric acid (HF). Thus, the fourth interlayer insulating film 12 in the memory cell unit 51 is removed, and the outer wall surfaces of the bottom electrodes 13 are exposed. Moreover, the protection film 13a filled in the insides of the bottom electrodes 13 is removed.

During the wet-etching process, the third interlayer insulating film 11 formed from the silicon nitride film functions as a stopper film that prevent etching of elements which are disposed on layers lower than the third interlayer insulating film 11.

Since the multi-stack film 14 is formed so as to cover the fourth interlayer insulating film 12 on the peripheral side, the fourth interlayer insulating film 12 on the peripheral side will not be removed.

Although not shown in the drawing, since the multi-stack film 14 is formed so as to cover the upper surface of the peripheral circuit portion 52, the peripheral circuit portion 52 will not be removed by the chemical solution.

Subsequently, a capacitor insulating film (not shown) is formed so as to cover the outer wall surfaces of each of the bottom electrodes 13.

As the capacitor insulating film, oxides such as hafnium oxide (HfO₂), zirconium oxide (ZrO₂), or aluminum oxide (Al₂O₃) and a high dielectric film formed from a stack or the like of the above-mentioned oxides can be used, for example.

After that, a top electrode 15 formed from a titanium nitride film is formed so as to cover the bottom electrodes 13 and the supporter 14S. The top electrode 15 has a structure in which the capacitor insulating film is interposed between the bottom electrodes 13 and the top electrode 15, whereby a capacitor element Ca is formed.

As the top electrode 15, a metal film other than the titanium nitride film may also be used. Moreover, as the top electrode 15, polycrystalline silicon or the like may be stacked on the titanium nitride film. In this way, the voids occurring between the bottom electrodes 13 can be filled more closely.

Subsequently, a fifth interlayer insulating film 20 formed from silicon oxide or the like is formed so as to cover the top electrode 15.

After that, a lead-out contact plug (not shown) for applying potential (plate potential) to the top electrode 15 of the capacitor element is formed.

Subsequently, the multi-stack film 14 on the peripheral circuit portion 52 is removed, wherein the multi-stack film 14 has been unnecessary after wet-etching process. By removing the multi-stack film 14 on the peripheral circuit portion 52, dry-etching for forming contact holes can be carried out easily at the time of forming contact plugs that are connected to the electrodes of a MOS transistor provided on the peripheral circuit portion 52.

After that, a wiring layer 21 formed from aluminum (Al), copper (Cu), or the like is formed on the fifth interlayer insulating film 20.

Subsequently, a surface protection film 22 formed from silicon oxynitride (SiON) or the like is formed so as to cover the fifth interlayer insulating film 20 and the wiring layer 21.

By the above processes, a semiconductor device (DRAM device) 50 according to an embodiment of the invention shown in FIG. 1 to FIGS. 5A and 5B is manufactured.

The semiconductor device 50 according to an embodiment of the invention includes plural electrodes (bottom electrodes) 13 standing on the semiconductor substrate 1 and the supporter 14S that holds the standing of the electrodes 13, in which the supporter 14S is the multi-stack film 14 in which the first support film 14a having a compressive stress and the second support film 14b having a tensile stress are stacked. Therefore, even when the bottom electrodes 13 of the capacitor elements are supported by the supporter 14S, and wet-etching process is carried out so as to expose the outer wall surfaces of each of the bottom electrodes 13, collapse of the bottom electrodes 13 can be prevented. Moreover, since the supporter 14S is formed by laminating at least two layers of film having different stress directions, the stress of the supporter 14S can be relaxed. Even when the outer wall surfaces of each of the bottom electrodes 13 of the capacitors Ca are exposed during wet-etching process of the manufacturing process of the capacitors Ca, no cracks will be formed in the supporter 14S that supports the bottom electrodes 13 of the capacitors Ca. The supporter 14S will maintain its strength, and collapse of the bottom electrodes 13 can be prevented.

Even when the bottom electrodes 13 are miniaturized further, collapse of the bottom electrodes 13 during wet-etching process can be prevented.

The supporter 14S strongly supports the bottom electrodes 13 by making contact with the outer wall surfaces of each of the bottom electrodes 13 at the openings 12A and connects the bottom electrodes 13 adjacent in the extending direction thereof. Since the supporter 14S makes contact with the outer wall surfaces of each of the bottom electrodes at least a partial region, the bottom electrodes 13 can be held stably.

Since the multi-stack film 14 has chemical resistance to hydrofluoric acid, the peripheral circuit portion 52 can be protected from a chemical solution during the etching process.

In the semiconductor device 50 according to an embodiment of the invention, either one or both of the first and second support films 14a and 14b has at least two layers, and the first and second support films 14a and 14b are stacked alternately. Therefore, by laminating at least two layers of film having different stress directions, the stress of the supporter 14S can be relaxed. Even when the outer wall surfaces of each of the bottom electrodes 13 of the capacitors Ca are exposed during wet-etching process of the manufacturing process of the capacitors Ca, no cracks will be formed in the supporter 14S that supports the bottom electrodes 13 of the capacitors Ca. The supporter 14S will maintain its strength, and collapse of the bottom electrodes 13 can be prevented.

In the semiconductor device 50 according to an embodiment of the invention, the electrodes (bottom electrodes) 13 have a cylindrical shape. Therefore, by laminating at least two layers of film having different stress directions, the stress of the supporter 14S can be relaxed. Even when the outer wall surfaces of each of the bottom electrodes 13 of the capacitors Ca are exposed during wet-etching process of the manufacturing process of the capacitors Ca, no cracks will be formed in the supporter 14S that supports the bottom electrodes 13 of the capacitors Ca. The supporter 14S will maintain its strength, and collapse of the bottom electrodes 13 can be prevented.

In the semiconductor device 50 according to an embodiment of the invention, at least one of the first and second support films 14a and 14b is a silicon nitride (SiN) film. Therefore, by laminating at least two layers of film having different stress directions, the stress of the supporter 14S can be relaxed. Even when the outer wall surfaces of each of the bottom electrodes 13 of the capacitors Ca are exposed during wet-etching process of the manufacturing process of the capacitors Ca, no cracks will be formed in the supporter 14S that supports the bottom electrodes 13 of the capacitors Ca. The supporter 14S will maintain its strength, and collapse of the bottom electrodes 13 can be prevented.

The semiconductor device 50 according to an embodiment of the invention includes the capacitor elements Ca each having the electrode (bottom electrode) 13, the capacitor insulating film formed on the lateral surfaces of the electrode 13, and another electrode 15 formed so as to interpose the capacitor insulating film between the electrodes 13 and 15. Therefore, by laminating at least two layers of film having different stress directions, the stress of the supporter 14S can be relaxed. Even when the outer wall surfaces of each of the bottom electrodes 13 of the capacitors Ca are exposed during wet-etching process of the manufacturing process of the capacitors Ca, no cracks will be formed in the supporter 14S that supports the bottom electrodes 13 of the capacitors Ca. The supporter 14S will maintain its strength, and collapse of the bottom electrodes 13 can be prevented.

A method for manufacturing the semiconductor device 50 according to an embodiment of the invention includes the steps of: forming plural contact pads 10 on the semiconductor substrate 1; forming the interlayer insulating film 12 so as to cover the contact pads 10; forming the multi-stack film 14 on the interlayer insulating film 12, the multi-stack film 14 being obtained by laminating the first support film 14a having a compressive stress and the second support film 14b having a tensile stress; forming the openings 12A so as to penetrate through the interlayer insulating film 12 and the multi-stack film 14 and expose the contact pads 10; forming plural electrodes (bottom electrodes) 13 so as to be in contact with the contact pads 10 and cover the inner surfaces of the openings 12A; patterning the multi-stack film 14 so as to form the supporter 14S making contact with at least a portion of the respective electrodes 13; and wet-etching the interlayer insulating film 12 so as to expose the outer wall surfaces of each of the electrodes 13. Therefore, by laminating at least two layers of film having different stress directions, the stress of the supporter 14S can be relaxed. Even when the outer wall surfaces of each of the bottom electrodes 13 of the capacitors Ca are exposed during wet-etching process of the manufacturing process of the capacitors Ca, no cracks will be formed in the supporter 14S that supports the bottom electrodes 13 of the capacitors Ca. The supporter 14S will maintain its strength, and collapse of the bottom electrodes 13 can be prevented.

In the manufacturing method of the semiconductor device 50 according to an embodiment of the invention, the first support film 14a is formed by a HDP-CVD method, and the second support film 14b is formed by an ALD method or an LP-CVD method. Therefore, by laminating at least two layers of film having different stress directions, the stress of the supporter 14S can be relaxed. Even when the outer wall surfaces of each of the bottom electrodes 13 of the capacitors Ca are exposed during wet-etching process of the manufacturing process of the capacitors Ca, no cracks will be formed in the supporter 14S that supports the bottom electrodes 13 of the capacitors Ca. The supporter 14S will maintain its strength, and collapse of the bottom electrodes 13 can be prevented.

### Second Embodiment

Another example of a semiconductor device according to an embodiment of the invention will be described. In the following description, the same constituent elements as those shown in the first embodiment will be denoted by the same reference numerals.

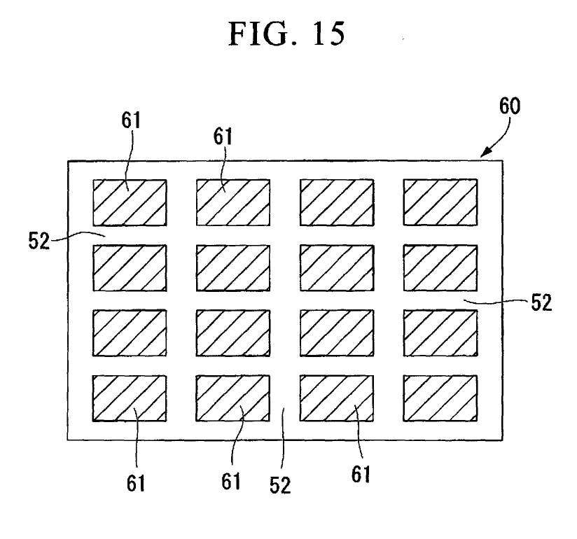

FIG. 15 is a conceptual diagram showing another example of a top-view structure of a semiconductor device according to an embodiment of the invention. As shown in FIG. 15, a semiconductor device 60 according to an embodiment of the present invention is a DRAM device having an approximately rectangular shape in top view. The semiconductor device 60 includes plural memory cell units 61 having an approximately rectangular shape in top view and a peripheral circuit portion 52.

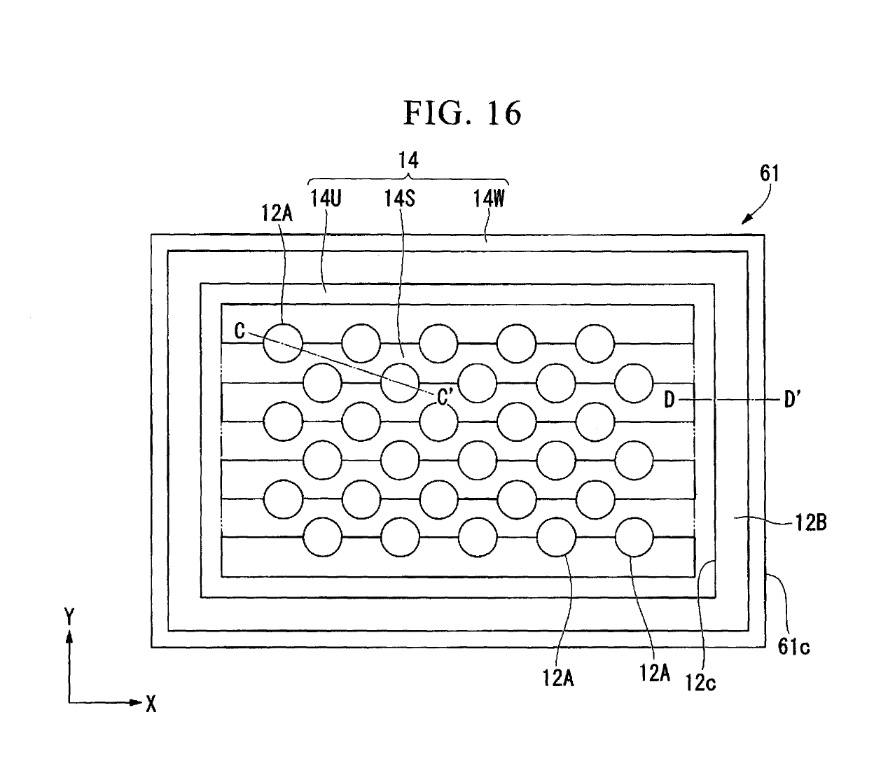

FIG. 16 is a conceptual top-view diagram of the memory cell unit of the semiconductor device shown in FIG. 15.

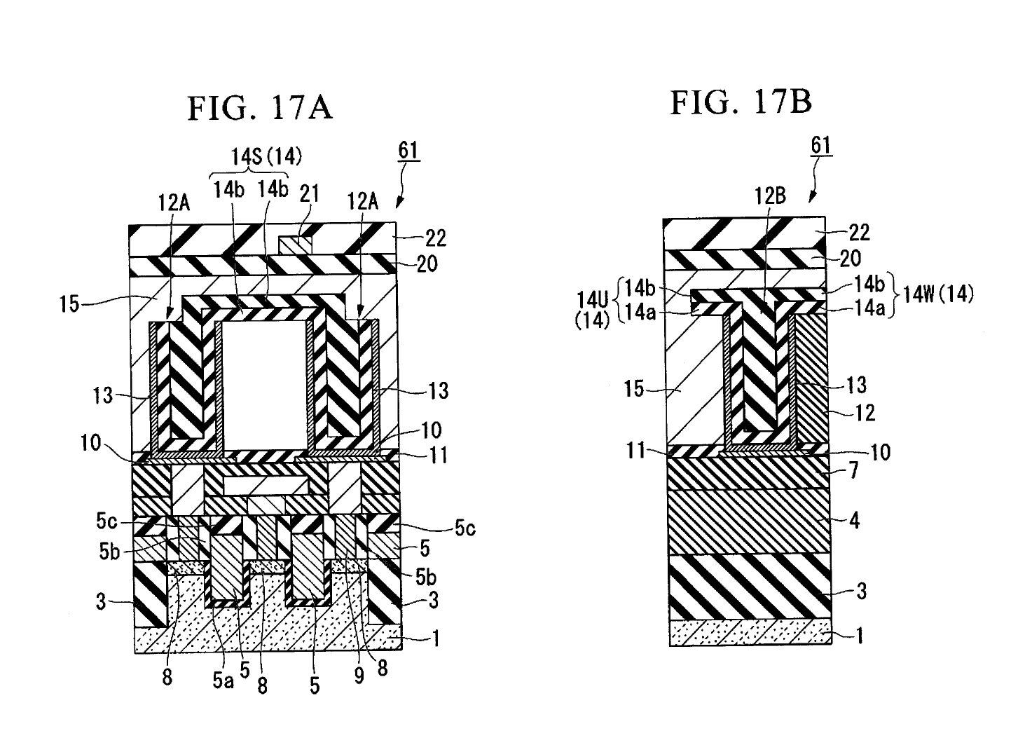

FIGS. 17A and 17B are diagrams of the memory cell unit shown in FIG. 16, in which FIG. 17A is a cross-sectional view along the line C-C′ in FIG. 16, and FIG. 17B is a cross-sectional view along the line D-D′ in FIG. 16.

As shown in FIGS. 17A and 17B, in the semiconductor device 60 according to an embodiment of the present invention, a portion of the supporter 14S is filled in the cylinder of the bottom electrode 13. Moreover, the portion of the supporter 14S filled in the cylinder of the bottom electrode 13 includes the first and second support films 14a and 14b.

A method for manufacturing the semiconductor device 60 according to an embodiment of the present invention will be described.

First, the same manufacturing processes as the manufacturing method shown by the cross-sectional process diagrams in FIGS. 6A and 6B to FIGS. 11A and 11B of the first embodiment are performed.

Subsequently, a fourth interlayer insulating film 12 formed from silicon oxide or the like is deposited to a thickness of 2 μm, for example, so as to cover the third interlayer insulating film 11.

Subsequently, openings are formed at the formation positions 12A of the bottom electrodes of the capacitor elements by anisotropic dry-etching so as to expose the surfaces of the capacitor contact pads 10. At the same time, an outer trench 12B is formed along the periphery of the memory cell unit 61 so as to expose the surfaces of the capacitor contact pads 10.

After that, a conductive film 13b formed from a titanium nitride film is formed so as to cover the surface of the fourth interlayer insulating film 12 and the inner surfaces of the openings 12A and the outer trench 12B.

Subsequently, the conductive film 13b is subjected to patterning using a photoresist pattern as a mask, and the patterned conductive film 13b is used as bottom electrodes 13.

After that, a first support film 14a formed from silicon nitride film is deposited by the HDP-CVD method so as to cover the fourth interlayer insulating film 12 and the inner surfaces of the bottom electrodes 13. The thickness of the first support film 14a formed from the silicon nitride film is set to be about 50 nm, for example.

Subsequently, a second support film 14b formed from a silicon nitride film is deposited by the ALD method so as to cover the first support film 14a and fill the insides of the openings 12A and the outer trench 12W. The thickness of the second support film 14b formed from the silicon nitride film is set to be about 50 nm, for example.

After that, the multi-stack film 14 is subjected to patterning using a photoresist pattern as a mask. In this way, the multi-stack film 14 is patterned into a supporter 14S, an inner frame 14U, and an outer frame 14W.

Subsequently, wet-etching process is performed using a chemical solution containing hydrofluoric acid (HF). Thus, the fourth interlayer insulating film 12 in the memory cell unit 61 is removed, and the outer wall surfaces of the bottom electrodes 13 are exposed. In this case, since the multi-stack film 14 is formed so as to cover the fourth interlayer insulating film 12 on the peripheral side, the fourth interlayer insulating film 12 on the peripheral side will not be removed.

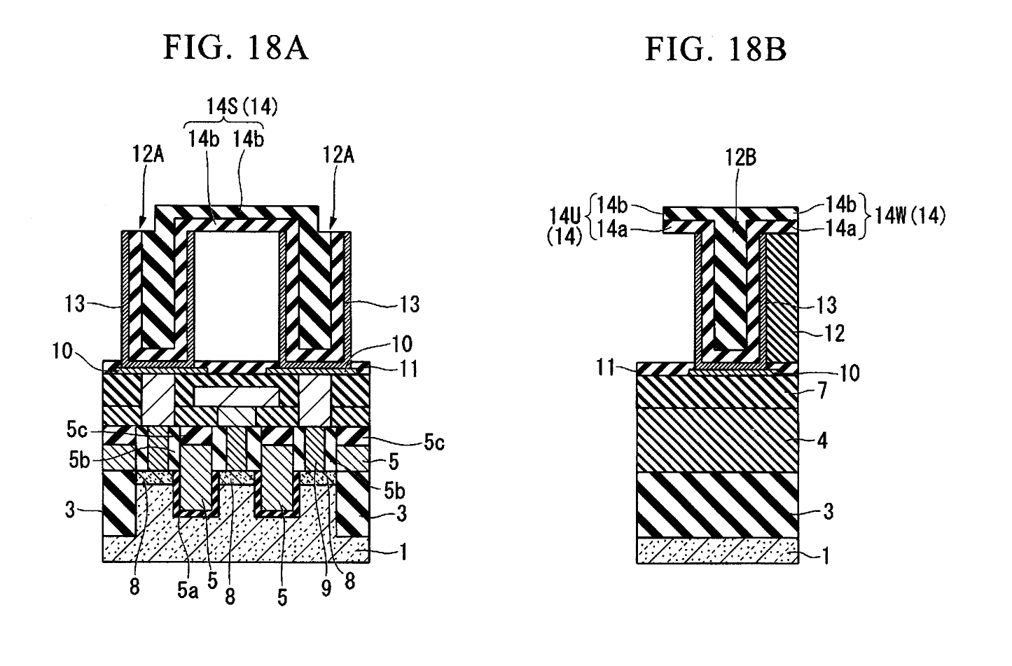

FIGS. 18A and 18B are diagrams showing another example of the manufacturing method of the semiconductor device according to the invention and are cross-sectional process diagrams of the memory cell unit 61 of the semiconductor device 60 after the wet-etching process is performed. Specifically, FIG. 18A is the cross-sectional process diagram along the line C-C′ in FIG. 16, and FIG. 18B is the cross-sectional process diagram along the line D-D′ in FIG. 16.

As shown in FIGS. 18A and 18B, a portion of the supporter 14S formed from the multi-stack film 14 is formed so as to fill the insides of the bottom electrodes 13. Since the supporter 14S is filled in the cylinders of the respective bottom electrodes 13, the supporter 14S holds the bottom electrodes 13 by being integrated with the multi-stack film 14 filled in the insides of the bottom electrodes 13. Therefore, the bottom electrodes 13 can be supported more strongly than the structure shown in the first embodiment.

In this embodiment, the inner wall surfaces of each of the bottom electrodes 13 may not be used for securing the electrostatic capacitance of the capacitor. However, since the strength of the bottom electrodes 13 can be improved, the electrostatic capacitance of the capacitor can be increased by increasing the height of the bottom electrodes 13. Even when the height of the bottom electrodes 13 is increased and the wet-etching time is increased, since the multi-stack film 14 is formed so as to cover the upper surface of the peripheral circuit portion 52, the chemical solution will not permeate through the peripheral circuit portion 52.

In the semiconductor device 60 according to an embodiment of the invention, a portion of the supporter 14S is filled in the cylinders of the electrodes (bottom electrodes) 13. Therefore, the portion of the supporter 14S filled in the cylinders of the bottom electrodes 13 will reinforce the supporter 14S, and collapse of the bottom electrodes 13 can be prevented.

In the semiconductor device 60 according to an embodiment of the invention, the portion of the supporter 14S filled in the cylinders of the electrodes (bottom electrodes) 13 includes the first and second support films 14a and 14b. Therefore, the portion of the multi-stack film 14 including the first and second support films 14a and 14b filled in the cylinders of the bottom electrodes 13 will reinforce the supporter 14S, and collapse of the bottom electrodes 13 can be prevented.

A method for manufacturing the semiconductor device 60 according to an embodiment of the invention includes the steps of: forming plural contact pads 10 on the semiconductor substrate 1; forming the interlayer insulating film 12 so as to cover the contact pads 10; forming the openings 12A so as to penetrate through the interlayer insulating film 12 and expose the contact pads 10; forming plural cylindrical electrodes 13 so as to be in contact with the contact pads 10 and cover the inner surfaces of the openings 12A; forming the multi-stack film 14 so as to cover the interlayer insulating film 12 and fill the cylinders of the cylindrical electrodes 13, the multi-stack film 14 being obtained by laminating the first support film 14a having a compressive stress and the second support film 14b having a tensile stress; patterning the multi-stack film 14 so as to form the supporter 14S making contact with at least a portion of the respective electrodes 13; and wet-etching the interlayer insulating film 12 so as to expose the outer wall surfaces of each of the electrodes 13. Therefore, by laminating at least two layers of film having different stress directions, the stress of the supporter 14S can be relaxed. Even when the outer wall surfaces of each of the bottom electrodes 13 of the capacitors Ca are exposed during wet-etching process of the manufacturing process of the capacitors Ca, no cracks will be formed in the supporter 14S that supports the bottom electrodes 13 of the capacitors Ca. The supporter 14S will maintain its strength, and collapse of the bottom electrodes 13 can be prevented.

### Third Embodiment

A further example of a semiconductor device according to an embodiment of the invention will be described. In the following description, the same constituent elements as those shown in the first embodiment will be denoted by the same reference numerals.

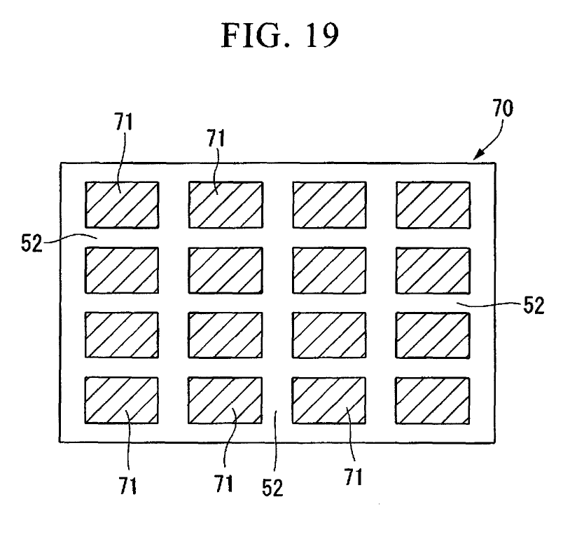

FIG. 19 is a conceptual diagram showing another example of a top-view structure of a semiconductor device according to an embodiment of the invention.

As shown in FIG. 19, a semiconductor device 70 according to an embodiment of the present invention is a DRAM device having an approximately rectangular shape in top view. The semiconductor device 70 includes plural memory cell units 71 having an approximately rectangular shape in top view and a peripheral circuit portion 52.

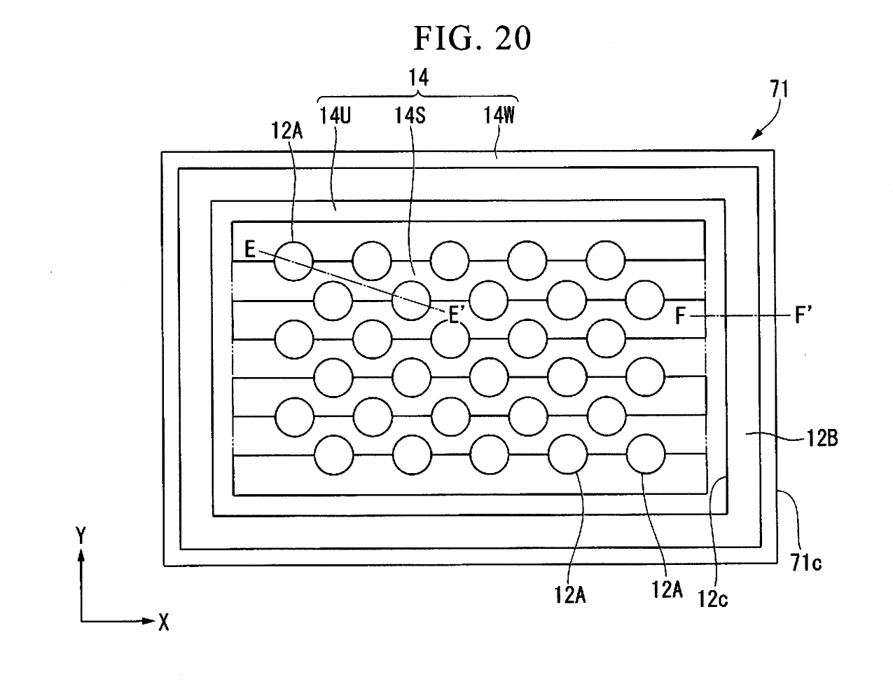

FIG. 20 is a conceptual top-view diagram of the memory cell unit of the semiconductor device shown in FIG. 19.

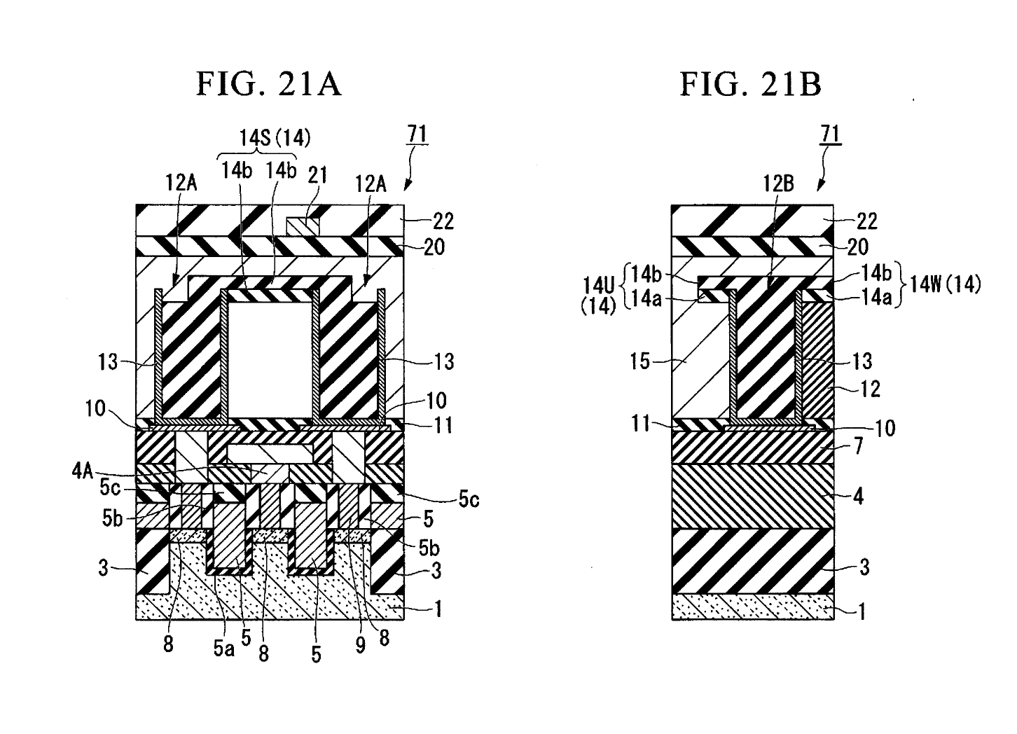

FIGS. 21A and 21B are diagrams of the memory cell unit shown in FIG. 20, in which FIG. 21A is a cross-sectional view along the line E-E′ in FIG. 19, and FIG. 21B is a cross-sectional view along the line F-F′ in FIG. 19.

As shown in FIGS. 21A and 21B, in the semiconductor device 70 according to an embodiment of the present invention, a portion of the supporter 14S is filled in the cylinder of the bottom electrode 13. Moreover, the portion of the supporter 14S filled in the cylinder of the bottom electrode 13 includes the first and second support films 14a and 14b.

Next, a method for manufacturing the semiconductor device 70 according to an embodiment of the present invention will be described.

First, the same manufacturing processes as the manufacturing method shown by the cross-sectional process diagrams in FIGS. 6A and 6B to FIGS. 11A and 11B of the first embodiment are performed.

Subsequently, a fourth interlayer insulating film 12 formed from silicon oxide or the like is deposited to a thickness of 2 μm, for example, so as to cover the third interlayer insulating film 11.

After that, a first support film 14a formed from silicon nitride film is deposited by the HDP-CVD method so as to cover the fourth interlayer insulating film 12. The thickness of the first support film 14a formed from the silicon nitride film is set to be about 50 nm, for example.

Subsequently, openings are formed at the formation positions 12A of the bottom electrodes of the capacitor elements by anisotropic dry-etching so as to expose the surfaces of the capacitor contact pads 10. At the same time, an outer trench 12B is formed along the periphery of the memory cell unit 71 so as to expose the surfaces of the capacitor contact pads 10.

After that, a conductive film 13b formed from a titanium nitride film is formed so as to cover the surface of the first support film 14a and the inner surfaces of the openings 12A and the outer trench 12B.

Subsequently, the conductive film 13b is subjected to patterning using a photoresist pattern as a mask. In this way, the patterned conductive film 13b is used as bottom electrodes 13.

Subsequently, a second support film 14b formed from a silicon nitride film is deposited by the ALD method so as to cover the first support film 14a and fill the insides of the bottom electrodes 13. The thickness of the second support film 14b is set to be about 50 nm, for example.

After that, the second support film 14b is subjected to patterning using a photoresist pattern as a mask, whereby a supporter 14S, an inner frame 14U, and an outer frame 14W are formed.

Subsequently, wet-etching process is performed using a chemical solution containing hydrofluoric acid (HF). Thus, the fourth interlayer insulating film 12 in the memory cell unit 71 is removed, and the outer wall surfaces of the bottom electrodes 13 are exposed. In this case, since the multi-stack film 14 is formed so as to cover the fourth interlayer insulating film 12 on the peripheral side, the fourth interlayer insulating film 12 on the peripheral side will not be removed.

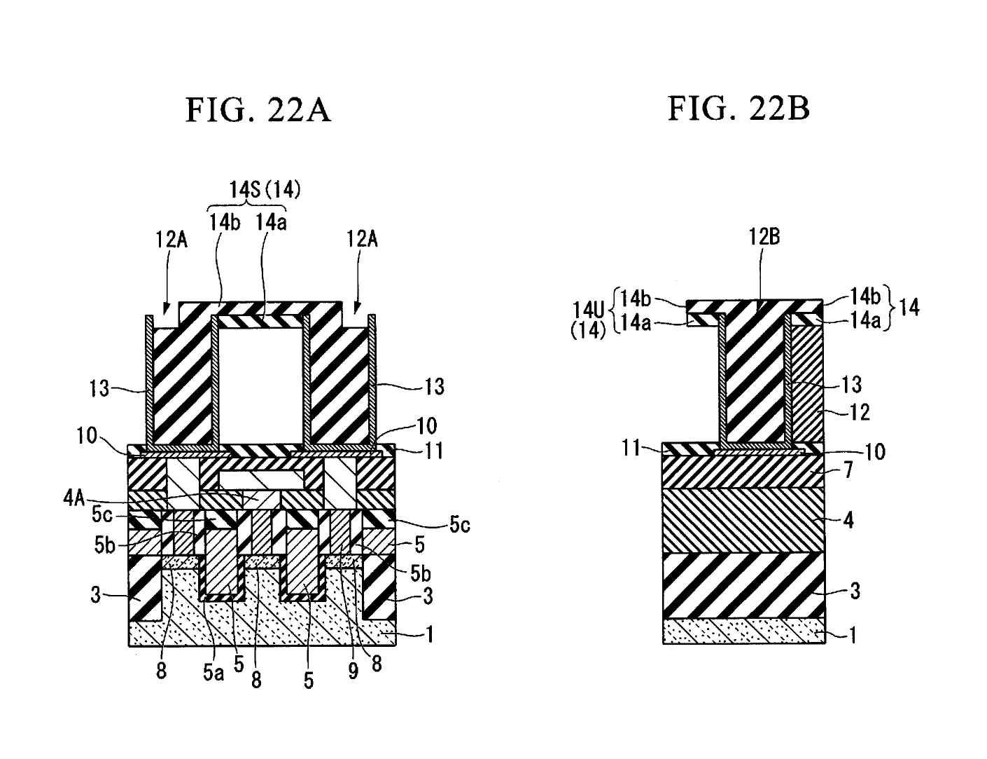

FIGS. 22A and 22B are diagrams showing another example of the manufacturing method of the semiconductor device according to the invention and are cross-sectional process diagrams of the memory cell unit 71 of the semiconductor device 70 after the wet-etching process is performed. Specifically, FIG. 22A is the cross-sectional process diagram along the line E-E′ in FIG. 20, and FIG. 22B is the cross-sectional process diagram along the line F-F′ in FIG. 20.

As shown in FIGS. 22A and 22B, a portion of the supporter 14S formed from the multi-stack film 14 is formed so as to fill the insides of the bottom electrodes 13. Since the supporter 14S is filled in the cylinders of the respective bottom electrodes 13, the supporter 14S holds the bottom electrodes 13 by being integrated with the multi-stack film 14 filled in the insides of the bottom electrodes 13. Therefore, the bottom electrodes 13 can be supported more strongly than the structure shown in the first embodiment.

In this embodiment, the inner wall surfaces of each of the bottom electrodes 13 may not be used for securing the electrostatic capacitance of the capacitor. However, since the strength of the bottom electrodes 13 can be improved, the electrostatic capacitance of the capacitor can be increased by increasing the height of the bottom electrodes 13. Even when the height of the bottom electrodes 13 is increased and the wet-etching time is increased, since the multi-stack film 14 is formed so as to cover the upper surface of the peripheral circuit portion 52, the chemical solution will not permeate through the peripheral circuit portion 52.

When the semiconductor device is miniaturized further, the widths (inner diameters) of the openings 12A are decreased, and it is difficult to secure a space in the bottom electrodes 13 in which the multi-stack film 14 is filled. In this case, by using the structure shown in this embodiment, the bottom electrodes 13 can be held strongly.

In the semiconductor device 70 according to an embodiment of the invention, a portion of the supporter 14S is filled in the cylinders of the bottom electrodes 13. Therefore, the portion of the supporter 14S filled in the cylinders of the bottom electrodes 13 will reinforce the supporter 14S, and collapse of the bottom electrodes 13 can be prevented.

In the semiconductor device 70 according to an embodiment of the invention, the portion of the supporter 14S filled in the cylinders of the bottom electrodes 13 includes the first and second support films 14a and 14b. Therefore, a portion of the first or second support film 14a or 14b filled in the cylinders of the bottom electrodes 13 will reinforce the supporter 14S, and collapse of the bottom electrodes 13 can be prevented.

A method for manufacturing the semiconductor device 50 according to an embodiment of the invention includes the steps of: forming plural contact pads 10 on the semiconductor substrate 1; forming the interlayer insulating film 12 so as to cover the contact pads 10; forming either one of the first support film 14a having a compressive stress and the second support film 14b having a tensile stress on the interlayer insulating film 12; forming the openings 12A so as to penetrate through the interlayer insulating film 12 and the support film and expose the contact pads 10; forming plural cylindrical electrodes 13 so as to be in contact with the contact pads 10 and cover the inner surfaces of the openings 12A; forming the other one of the first and second support films 14a and 14b so as to cover the support film and fill the cylinders of the cylindrical electrodes 13 and forming the multi-stack film 14 between the electrodes 13, the multi-stack film 14 being obtained by laminating the first and second support films 14a and 14b; patterning the multi-stack film 14 so as to form the supporter 14S making contact with at least a portion of the respective electrodes 13; and wet-etching the interlayer insulating film 12 so as to expose the outer wall surfaces of each of the electrodes 13. Therefore, by laminating at least two layers of film having different stress directions, the stress of the supporter 14S can be relaxed. Even when the outer wall surfaces of each of the bottom electrodes 13 of the capacitors Ca are exposed during wet-etching process of the manufacturing process of the capacitors Ca, no cracks will be formed in the supporter 14S that supports the bottom electrodes 13 of the capacitors Ca. The supporter 14S will maintain its strength, and collapse of the bottom electrodes 13 can be prevented.

### EXAMPLES

Hereinafter, the invention will be described in detail based on examples. However, the invention is not limited to these examples.

### Example 1

A semiconductor device of Example 1 shown in FIG. 1 to FIGS. 5A and 5B was manufactured in the manner described below.

First, by the STI method, trenches were formed on one surface (principal surface) 1a of a semiconductor substrate 1 formed from P-type silicon and subjected to predetermined cleaning treatment. After that, silicon oxide (SiO₂) was filled in the trenches, whereby device separation regions 3 were formed.

Subsequently, the silicon in the semiconductor substrate 1 was etched using a photoresist pattern as a mask, whereby trenches 2 for gate electrodes 5 of a MOS transistor TR were formed in an active region K partitioned by the device separation regions 3.

Subsequently, the surface of the silicon in the semiconductor substrate 1 was oxidized by the thermal oxidation method, whereby a thermal oxidation film (gate insulating film) formed from silicon oxide having a thickness of 4 nm was formed.

After that, by the CVD method using monosilane (SiH₄) and phosphine (PH₃) as the raw material gas, a polycrystalline silicon film containing phosphorus was deposited to a thickness such that the insides of the trenches 2 were completely filled with the polycrystalline silicon film.

Subsequently, a metal film formed from tungsten was deposited to a thickness of 50 nm on the polycrystalline silicon film by the sputtering method.

Subsequently, by the plasma CVD method using monosilane and ammonia (NH₃) as the raw material gas, a cap layer 5c formed from an insulating film such as silicon nitride was deposited to a thickness of 70 nm on the metal film.

After that, after a photoresist was deposited on the cap layer 5c, a photoresist pattern for forming the gate electrodes 5 was formed using a mask by a photolithography method. Then, the cap layer 5c was etched using the photoresist pattern as a mask.

Subsequently, after the photoresist pattern was removed, the metal film and the polycrystalline silicon film were etched using the cap layer 5c as a hard mask, whereby the gate electrodes 5 were formed.

After that, phosphorus (P) serving as an N-type impurity was ion-implanted to the principal surface 1a of the semiconductor substrate 1 in the active region K, whereby an impurity diffusion layer 8 was formed.

Subsequently, by the CVD method, a silicon nitride film was deposited to a thickness of 20 nm so as to cover the principal surface la of the semiconductor substrate 1. After that, the silicon nitride film was etched back, whereby sidewalls 5b were formed so as to cover the lateral walls of the gate electrodes 5.

Subsequently, by the CVD method, a gate interlayer insulating film 40 formed from silicon oxide or the like was formed so as to cover the cap layer 5c and the sidewalls 5b. After that, by the CMP method, the surface of the gate interlayer insulating film 40 was polished until the upper surface of the cap layer 5c was exposed, whereby unevenness resulting from the gate electrodes 5 was planarized.

Subsequently, a mask formed from a photoresist pattern was formed so as to form openings at the positions of the substrate contacts 205a, 205b, and 205c, and etching was carried out. The openings were provided between the gate electrodes 5 by self-alignment using the cap layer 5c and the sidewalls 5b.

After that, a phosphorus-containing polycrystalline silicon film was deposited onto the principal surface 1a of the semiconductor substrate 1 by the CVD method. Then, the surface of the polycrystalline silicon film was polished by the CMP method until the surface of the cap layer 5c was exposed. In this way, substrate contact plugs 9 formed from the polycrystalline silicon film filled in the openings were formed.

Subsequently, by the CVD method, a first interlayer insulating film 4 formed from silicon oxide was formed to a thickness of about 600 nm, for example, so as to cover the cap layer 5c, the sidewalls 5b, the substrate contact plugs 9, and the gate interlayer insulating film 40. After that, the first interlayer insulating film 4 was polished by the CMP method so that the thickness after polishing became 300 nm.

Subsequently, a contact hole that penetrates through the first interlayer insulating film 4 was formed at the position of the substrate contact 205a so as to expose the surface of one substrate contact plug 9. Then, a multi-stack film obtained by depositing tungsten (W) on a barrier film of TiN/Ti was formed so as to fill the contact hole.

After that, the surface of the multi-stack film was polished by the CMP method, and the multi-stack film was used as a bit-line contact plug 4A.

Subsequently, a bit line 6 was formed on the first interlayer insulating film 4 so as to be connected to the bit-line contact plug 4A. After that, a second interlayer insulating film 7 formed from silicon oxide or the like was formed so as to cover the bit line 6 and the first interlayer insulating film 4.

Subsequently, contact holes that penetrate through the first and second interlayer insulating films 4 and 7 were formed at the positions of the other substrate contacts 205b and 205c so as to expose the surfaces of the substrate contact plugs 9. Then, multi-stack films obtained by laminating tungsten (W) on a barrier film of TiN/Ti were formed so as to fill these contact holes.

After that, the surfaces of the multi-stack films are polished by the CMP method, and the multi-stack films are used as capacitor contact plugs 7A.

Subsequently, capacitor contact pads 10 formed from a multi-stack film including tungsten were formed on the second interlayer insulating film 7 so as to be connected to the capacitor contact plugs 7A. In this way, electrical connection between the capacitor contact plugs 7A and the capacitor contact pads 10 was ensured. The sizes of the capacitor contact pads 10 were set so as to be twice the size of the bottom of the bottom electrode of a capacitor element.

Moreover, in the peripheral region of the memory cell unit 51, the capacitor contact pad 10 was formed at the position where the outer trench 12B was formed.

After that, a third interlayer insulating film 11 formed from silicon nitride was deposited to a thickness of 60 nm so as to cover the capacitor contact pads 10 and the second interlayer insulating film 7.

Subsequently, a fourth interlayer insulating film 12 formed from silicon oxide or the like was deposited to a thickness of 2 μm so as to cover the third interlayer insulating film 11.

After that, semiconductor substrates 1 having the fourth interlayer insulating film 12 deposited thereon were mounted one by one on a stage provided in a chamber (reaction chamber) of a HDP-CVD deposition apparatus. The temperature of the semiconductor substrate 1 mounted on the stage was adjusted to be in a range of 450 to 500° C.

Subsequently, raw material gas was supplied into the chamber, and the inside of the chamber was maintained to be at a predetermined degree of vacuum by a vacuum pump. Silane (SiH₄) gas and nitrogen (N₂) gas were used as the raw material gas, and inert gas such as argon (Ar) was used as carrier gas. For example, the flow rate of SiH₄ gas was set to 150 to 250 sccm, and the flow rate of N₂ gas was set to 200 to 300 sccm.

After that, a high-frequency power (hereinafter referred to as a source power) was supplied from an RF generator to coils arranged so as to surround the chamber, whereby inductively coupled plasma was generated in the chamber. The source power was set to 7500 to 12000 W.

A high-frequency power (hereinafter referred to as a bias power) for independent control was added to the stage mounting the semiconductor substrate 1 thereon from an RF generator provided separately. The bias power was set to 500 to 1500 W.

In this state, plasma was generated in the chamber of the HDP-CVD deposition apparatus. At that time, the source power and the bias power were controlled independently so as to control the movement of ions contributing to deposition and regulate the state of a deposited film.

In this way, a first support film 14a formed from silicon nitride film was deposited by the HDP-CVD method so as to cover the fourth interlayer insulating film 12. The thickness of the first support film 14a formed from the silicon nitride film was set to be 50 nm.

Subsequently, plural semiconductor substrates 1 having the first support film 14a deposited thereon were accommodated to be spaced by a predetermined distance in a process tube (reaction chamber) of an ALD deposition apparatus. As the ALD deposition apparatus, a batch-type vertical hot-wall apparatus capable of simultaneously processing plural semiconductor substrates was used. After that, the inside of the process tube was discharged by a vacuum pump to be maintained to be at a predetermined degree of vacuum.

Subsequently, the temperature of the semiconductor substrates 1 accommodated in the process tube was adjusted to be in a range of 400 to 650° C.

After that, silicon raw material gas was supplied so that a silicon film corresponding to approximately one layer of silicon atoms was adsorbed onto the semiconductor substrate 1 (first ALD process). In this case, dichlorosilane (SiH₂Cl₂) gas was used as the silicon raw material gas and supplied at a flow rate of 1 to 3 slm for a predetermined period of time.

Subsequently, nitrogen raw material gas was supplied while stopping the supply of silicon raw material gas so as to nitride the adsorbed silicon film with the plasma nitrogen raw material gas, whereby a silicon nitride film was formed (second ALD process). In this case, ammonia (NH₃) gas was used as the nitrogen raw material gas and supplied at a flow rate of 4 slm to 6 slm for a predetermined period of time.

The first and second ALD processes were repeated alternately, whereby a silicon nitride having a desired thickness was deposited.

During the first and second ALD processes, purge gas such as nitrogen (N₂) gas was supplied so as to discharge remaining gas out of the process tube.

In this way, a second support film 14b formed from silicon nitride was deposited by the ALD method so as to cover the first support film 14a. The thickness of the second support film 14b formed from the silicon nitride was set to be 50 nm.

Subsequently, openings were formed at the formation positions 12A of the bottom electrodes of the capacitor elements by anisotropic dry-etching so as to expose the surfaces of the capacitor contact pads 10. At the same time, an outer trench 12B was formed along the periphery of the memory cell unit 51 so as to expose the surfaces of the capacitor contact pads 10. After that, a titanium nitride film 13b was formed so as to cover the surface of the multi-stack film 14 and the inner surfaces of the openings 12A and the outer trench 12B.

Subsequently, a protection film 13a formed from a silicon oxide film was formed so as to fill the insides of the openings 12A and the outer trench 12B and cover the multi-stack film 14.

After that, the surface of the protection film 13a was polished by the CMP method until the titanium nitride film 13b was exposed. The titanium nitride film 13b was used as the bottom electrodes 13.

Subsequently, the multi-stack film 14 was subjected to patterning using a photoresist pattern as a mask. The multi-stack film 14 was patterned into a supporter 14S, an inner frame 14U, and an outer frame 14W.

After that, wet-etching process was performed using a chemical solution containing hydrofluoric acid (HF). Thus, the fourth interlayer insulating film 12 in the memory cell unit 51 was removed, and the outer wall surfaces of the bottom electrodes 13 were exposed. Moreover, the protection silicon oxide film 13a filled in the insides of the bottom electrodes 13 was removed. At that time, since the multi-stack film 14 was formed so as to cover the fourth interlayer insulating film 12 on the peripheral side, the fourth interlayer insulating film 12 on the peripheral side was not removed.

In this way, the cross-sectional structure shown in FIGS. 14A and 14B was manufactured after wet-etching process was performed. In the cross-sectional structure, the upper ends of the bottom electrodes 13 of the capacitor elements were held by the supporter 14S. Even when the wet-etching process was performed so as to expose the outer wall surfaces of the bottom electrodes 13, the bottom electrodes 13 did not collapse. Moreover, since the supporter 14S was formed by the stress-relaxed multi-stack film 14, even when the fourth interlayer insulating film 12 positioned at the lower end of the supporter 14S was removed by the wet-etching process, no cracks were formed in the supporter 14S.

The third interlayer insulating film 11 formed from the silicon nitride film functioned as a stopper film at the time of the wet-etching process. Thus, elements disposed on layers lower than the third interlayer insulating film 11 were not etched. Moreover, since the multi-stack film 14 was formed so as to cover the upper surface of the peripheral circuit portion 52, the peripheral circuit portion 52 was not removed by the chemical solution.

Subsequently, a capacitor insulating film formed from hafnium oxide (HfO₂) was formed so as to cover the outer wall surfaces of each of the bottom electrodes 13. After that, a top electrode 15 formed from a titanium nitride film was formed so as to cover the bottom electrodes 13 and the supporter 14S, whereby a capacitor element Ca was formed.

Subsequently, a fifth interlayer insulating film 20 formed from silicon oxide or the like was formed so as to cover the top electrode 15. After that, a lead-out contact plug for applying potential (plate potential) to the top electrode 15 of the capacitor element was formed. Subsequently, the multi-stack film 14 on the peripheral circuit portion 52 which had become unnecessary after wet-etching process was removed.

After that, a wiring layer 21 formed from aluminum (Al), copper (Cu), or the like was formed on the fifth interlayer insulating film 20. Subsequently, a surface protection film 22 formed from silicon oxynitride (SiON) was formed so as to cover the fifth interlayer insulating film 20 and the wiring layer 21.

By the above processes, a semiconductor device (DRAM device) shown in FIG. 1 to FIGS. 5A and 5B was manufactured.

### Example 2

A semiconductor device of Example 2 shown in FIG. 15 to FIGS. 17A and 17B was manufactured in a manner described below.

First, the processes before the deposition of the third interlayer insulating film 11 were performed similarly to Example 1.

Subsequently, a fourth interlayer insulating film 12 formed from silicon oxide or the like was deposited to a thickness of 2 μm so as to cover the third interlayer insulating film 11.

Subsequently, openings were formed at the formation positions 12A of the bottom electrodes of the capacitor elements by anisotropic dry-etching so as to expose the surfaces of the capacitor contact pads 10. At the same time, an outer trench 12B was formed along the periphery of the memory cell unit 61 so as to expose the surfaces of the capacitor contact pads 10.

After that, a titanium nitride film 13b was formed so as to cover the surface of the multi-stack film 14 and the inner surfaces of the openings 12A and the outer trench 12B. Subsequently, the titanium nitride film 13b was subjected to patterning using a photoresist pattern as a mask. Thus, the titanium nitride film 13b was patterned to the bottom electrodes 13.

After that, a first support film 14a formed from silicon nitride film was deposited by the HDP-CVD method so as to cover the fourth interlayer insulating film 12 and the inner surfaces of the bottom electrodes 13 which were formed so as to cover the inner surfaces of the openings 12A and the outer trench 12B. The thickness of the first support film 14a was set to be 50 nm.

Subsequently, a second support film 14b formed from a silicon nitride film was deposited by the ALD method so as to cover the first support film 14a and fill the insides of the bottom electrodes 13. The thickness of the second support film 14b formed from the silicon nitride film was set to be 50 nm.

Subsequently, the multi-stack film 14 was subjected to patterning using a photoresist pattern as a mask, whereby a supporter 14S, an inner frame 14U, and an outer frame 14W were formed.

After that, wet-etching process was performed using a chemical solution containing hydrofluoric acid (HF). Thus, the fourth interlayer insulating film 12 in the memory cell unit 61 was removed, and the outer wall surfaces of the bottom electrodes 13 were exposed. In this way, a cross-sectional structure shown in FIGS. 18A and 18B was manufactured.

In the cross-sectional structure shown in FIGS. 18A and 18B, since the upper ends of the bottom electrodes 13 of the capacitor elements were held by the supporter 14S, even when the wet-etching process was performed so as to expose the outer wall surfaces of the bottom electrodes 13, the bottom electrodes 13 did not collapse. Moreover, no cracks were formed in the supporter 14S.

Subsequently, similarly to Example 1, the capacitor insulating film, the top electrode 15, the fifth interlayer insulating film 20, the lead-out contact plug, the wiring layer 21, and the surface protection film were formed. By the above processes, a semiconductor device (DRAM device) of Example 2 shown in FIG. 15 to FIGS. 17A and 17B was manufactured.

### Example 3

A semiconductor device of Example 3 shown in FIG. 19 to FIGS. 21A and 21B was manufactured in a manner described below.

First, the processes before the deposition of the third interlayer insulating film 11 were performed similarly to Example 1.

Subsequently, a fourth interlayer insulating film 12 formed from silicon oxide or the like was deposited to a thickness of 2 μm so as to cover the third interlayer insulating film 11.

After that, a first support film 14a formed from a silicon nitride film was deposited by the HDP-CVD method so as to cover the fourth interlayer insulating film 12. The thickness of the first support film 14a was set to be 50 nm.

Subsequently, openings were formed at the formation positions 12A of the bottom electrodes of the capacitor elements by anisotropic dry-etching so as to expose the surfaces of the capacitor contact pads 10. At the same time, an outer trench 12B was formed along the periphery of the memory cell unit 71 so as to expose the surfaces of the capacitor contact pads 10.

After that, a titanium nitride film 13b was deposited so as to cover the surface of the first support film 14a and the inner surfaces of the openings 12A and the outer trench 12B.

Subsequently, the titanium nitride film 13b was subjected to patterning using a photoresist pattern as a mask, and the titanium nitride film 13b was patterned to the bottom electrodes 13.

Subsequently, a second support film 14b formed from a silicon nitride film was deposited by the ALD method so as to cover the first support film 14a and fill the insides of the bottom electrodes 13. The thickness of the second support film 14b was set to be 50 nm

Subsequently, the second support film 14b was subjected to patterning using a photoresist pattern as a mask, whereby a supporter 14S, an inner frame 14U, and an outer frame 14W were formed.

After that, wet-etching process was performed using a chemical solution containing hydrofluoric acid (HF). Thus, the fourth interlayer insulating film 12 in the memory cell unit 71 was removed, and the outer wall surfaces of the bottom electrodes 13 were exposed. In this way, a cross-sectional structure shown in FIGS. 22A and 22B was manufactured.

In the cross-sectional structure shown in FIGS. 22A and 22B, since the upper ends of the bottom electrodes 13 of the capacitor elements were held by the supporter 14S, even when the wet-etching process was performed so as to expose the outer wall surfaces of the bottom electrodes 13, the bottom electrodes 13 did not collapse. Moreover, no cracks were formed in the supporter 14S.

Subsequently, similarly to Example 1, the capacitor insulating film, the top electrode 15, the fifth interlayer insulating film 20, the lead-out contact plug, the wiring layer 21, and the surface protection film were formed.

By the above processes, a semiconductor device (DRAM device) of Example 3 shown in FIG. 19 to FIGS. 21A and 21B was manufactured.

The invention relates to a semiconductor device and a method of forming the same. More particularly, the invention relates to a semiconductor device having a supporter that prevents the occurrence of cracks and is capable of preventing collapse of a bottom electrode and a method of forming the same. The invention is applicable to industries that manufacture and use semiconductor devices.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
a plurality of first electrodes standing over a substrate; and
a supporter that supports the plurality of first electrodes in standing, the supporter comprising a stack of first and second supporting films, the first supporting film having a compressive stress, and the second supporting film having a tensile stress.

2. The semiconductor device according to claim 1, wherein the stack of first and second supporting films comprises an alternate stack of the first and second supporting films, the number of at least one of the first and second supporting films is two or more.

3. The semiconductor device according to claim 1, wherein the supporter is in contact with at least upper portions of the first electrodes.

4. The semiconductor device according to claim 1, wherein each of the plurality of first electrodes has a cylindrical shape and an inner space.

5. The semiconductor device according to claim 4, wherein the supporter includes filling portions that fill at least partially the inner spaces of the plurality of first electrodes.

6. The semiconductor device according to claim 5, wherein the filling portions of the supporter comprise at least one of the first and second supporting films.

7. The semiconductor device according to claim 1, wherein each of the plurality of first electrodes has pillar shapes.

8. The semiconductor device according to claim 1, wherein at least one of the first and second supporting films comprises a silicon nitride film.

9. The semiconductor device according to claim 1, further comprising:
a capacitive insulating film on a side surface of the first electrode; and
a second electrode on the capacitive insulating film, the first and second electrodes sandwiching the capacitive insulating film.

10. The semiconductor device according to claim 9, wherein the supporter comprises:
a frame portion; and
a supporting portion connected to the frame portion, the supporting portion being in contact with the plurality of first electrodes.

11. A semiconductor device comprising:
a plurality of memory cells, each memory cell comprising a transistor and a capacitor, the capacitor comprising first and second electrodes and an insulating film between the first and second electrodes, the first electrode being connected to the transistor electrically; and
a supporter that connects the first electrodes of the plurality of memory cells to each other, the supporter comprising a stack of first and second supporting films, the first supporting film having a compressive stress, and the second supporting film having a tensile stress.

12. The semiconductor device according to claim 11, wherein the supporter comprises:
a frame portion that surrounds the plurality of memory cells in plan view; and
a plurality of supporting portions connected to the frame portion, the plurality of supporting portions connecting the first electrodes of the plurality of memory cells to each other.

13. The semiconductor device according to claim 12, wherein the plurality of supporting portions are in contact with at least upper portions of the first electrodes.

14. The semiconductor device according to claim 11, wherein the supporter comprises an alternate stack of the first and second supporting films, the number of at least one of the first and second supporting films is two or more.

15. The semiconductor device according to claim 11, wherein the first electrodes have inner spaces and the supporter includes filling portions that fill at least partially the inner spaces of the first electrodes.

16. The semiconductor device according to claim 11, wherein the filling portions of the supporter comprise at least one of the first and second supporting films.

17. The semiconductor device according to claim 11, wherein at least one of the first and second supporting films comprises a silicon nitride film.

18. A semiconductor device comprising:
a plurality of first electrodes standing over a substrate; and
a supporter that connects the plurality of first electrodes to each other, the supporter having a stress-relaxing multi-layer structure which comprises first and second supporting layers which are different in stress direction from each other.

19. The semiconductor device according to claim 18, wherein the first supporting film has a compressive stress, and the second supporting film has a tensile stress.

20. The semiconductor device according to claim 18, wherein the first supporting film comprises an HDP-CVD silicon nitride film and the second supporting film comprises at least one of an ALD silicon nitride film and an LP-CVD silicon nitride film.
